(19) United States
(12) Patent Application Publication
(10) Pub. No.: US 2016/0137787 A1
(43) Pub. Date: May 19, 2016

(54) POLYMIDE PRECURSOR AND POLYMIDE

(71) Applicant: UBE INDUSTRIES, LTD., Yamaguchi (JP)

(72) Inventors: Takuya Oka, Ube-Shi (JP); Yukinori Kohama, Ube-shi (JP); Yoshiyuki Watanabe, Ube-shi (JP); Nobuharu Hisano, Ube-shi (JP)

(21) Appl. No.: 14/901,006

(22) PCT Filed: Jun. 26, 2014
(86) PCT No.: PCT/JP2014/067079

§ 371 Date: Dec. 22, 2015

(30) Foreign Application Priority Data
Jun. 27, 2013 (JP) 2013-135640

(51) Int. Cl. C08G 73/10; H05K 1/03; C09D 179/08

(52) U.S. Cl. CPC C08G 73/1028; C08G 73/1007; C08G 73/1039; C08G 73/1042; C08G 73/1078; C08G 73/1046; C09D 179/08; H05K 1/0353

(57) ABSTRACT

A polyimide precursor consisting of a repeating unit represented by the following chemical formula (1):

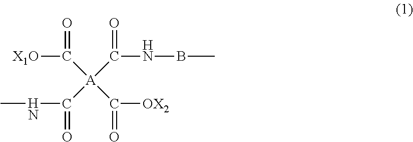

and
a repeating unit represented by the following chemical formula (2):

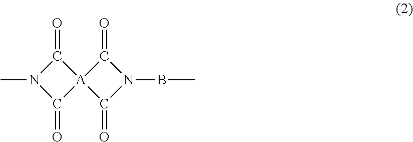

in which A is a tetravalent group of a tetracarboxylic acid, from which carboxyl groups have been removed; B is a divalent group of a diamine, from which amino groups have been removed; with the proviso that the A group and the B group contained in each repeating unit may be the same as, or different from each other; and X₁ and X₂ are each independently hydrogen, an alkyl group having 1 to 6 carbon atoms, or an alkylsilyl group having 3 to 9 carbon atoms,
the amount of the repeating unit represented by the chemical formula (2) is 30 mol % or more and 90 mol % or less relative to the total repeating units,
50 mol % or more of the total amount of the B group in the chemical formula (1) and the chemical formula (2) is p-phenylene group and/or a specific divalent group containing two or more benzene rings,
the polyimide precursor is produced by thermal imidization.

### TECHNICAL FIELD

The present invention relates to a polyimide precursor from which a polyimide having a low coefficient of linear thermal expansion, and having excellent heat resistance, solvent resistance and mechanical properties may be obtained.

### BACKGROUND ART

Polyimides have excellent heat resistance, solvent resistance (chemical resistance), mechanical properties, electric properties, and the like, and therefore have been widely used in electric/electronic device application, including flexible wiring board and tape for TAB (Tape Automated Bonding). A polyimide obtained from an aromatic tetracarboxylic dianhydride and an aromatic diamine, particularly polyimide obtained from 3,3′,4,4′-biphenyltetracarboxylic dianhydride and p-phenylenediamine, for example, is suitably used.

Meanwhile, studies of polyimides as an alternative to a glass substrate are advancing in the field of display devices. The replacement of a glass substrate by a plastic substrate such as polyimide enables a display which is light-weight and excellent in flexibility, and is capable of being bent and rolled. Although high transparency is required in such an application, wholly-aromatic polyimides obtained from an aromatic tetracarboxylic dianhydride and an aromatic diamine tend to be intrinsically yellowish-brown-colored due to the intramolecular conjugation and the formation of charge-transfer complexes. Consequently, as a means of reducing coloring, methods of developing transparency, for example, by introducing fluorine atom into the molecule, imparting flexibility to the main chain, introducing a bulky group as a side chain, or the like to suppress the intramolecular conjugation and the formation of charge-transfer complexes are proposed.

In addition, the use of a semi-alicyclic or wholly-alicyclic polyimide which does not form a charge-transfer complex in principle is also proposed. Patent Literatures 1 to 6 and Non Patent Literature 1, for example, disclose various semi-alicyclic polyimides having high transparency, in which an alicyclic tetracarboxylic dianhydride is used as the tetracarboxylic acid component and an aromatic diamine is used as the diamine component. Such a semi-alicyclic polyimide has transparency, bending resistance and high heat resistance. In general, there is a tendency for a semi-alicyclic polyimide to have a great coefficient of linear thermal expansion. A semi-alicyclic polyimide having a relatively low coefficient of linear thermal expansion, however, is also proposed.

In the application of flexible wiring board, tape for TAB, and the like, copper is generally laminated on a polyimide film. When the polyimide has a great coefficient of linear thermal expansion and the difference in the coefficient of linear thermal expansion between the polyimide and copper is great, warpage may occur in the laminate (laminated film), and therefore the processing accuracy may be decreased and the precise mounting of electronic components may be difficult. Accordingly, polyimide is required to have a low coefficient of linear thermal expansion.

On the other hand, in the field of display device, a conductive material such as metal is formed on a polyimide film which is a substrate. In this case, when the polyimide has a great coefficient of linear thermal expansion and the difference in the coefficient of linear thermal expansion between the polyimide and the conductive material is great, warpage may occur during the formation of a circuit board and the formation of a circuit may be difficult. Accordingly, there is need for polyimide having a low coefficient of linear thermal expansion.

As for a method for synthesizing polyimide by reacting a tetracarboxylic acid component and a diamine component, there are thermal imidization and chemical imidization. In general, a polyimide having a relatively low coefficient of linear thermal expansion may be obtained when the polyimide is produced by chemical imidization. However, a chemical imidizing agent (an acid anhydride such as acetic anhydride, and an amine compound such as pyridine and isoquinoline) may act as a plasticizer and the properties of the polyimide may be changed. In addition, a chemical imidizing agent may cause coloring, which is not preferred in applications where transparency is required.

On the other hand, in the case where the polyimide is produced by thermal imidization, the coefficient of linear thermal expansion may be reduced by heating and thermally imidizing a self-supporting film (also referred to as “gel film”) of a polyimide precursor solution after or while stretching the self-supporting film. However, a large-scale apparatus is required for stretching. In addition, it is necessary that a self-supporting film should be peeled off from a base plate, and then stretched after the self-supporting film is formed by flow-casting/applying a solution (or solution composition) of a polyimide precursor on the base plate and heating the solution. Accordingly, the technique may not be applicable to some applications. In the application of display, for example, a solution (or solution composition) of a polyimide precursor is flow-cast/applied on a base plate such as a glass substrate, and is heated and imidized to form a polyimide layer (polyimide film) on the base plate, and then a circuit, a thin-film transistor, and the like are formed on the polyimide layer of the obtained polyimide laminate. In this case, the coefficient of linear thermal expansion of the polyimide may not be reduced by stretching.

Meanwhile, a copolymer in which a part of the repeating unit of amic acid (or amide acid) structure is converted into imide structure [poly(amic acid-imide)copolymer] is also known as a polyimide precursor, and is disclosed in Patent Literatures 7 to 13 and Non Patent Literatures 2 to 4, for example.

Non Patent Literature 5 discloses that the coefficients of linear thermal expansion (CTE) of 6 different types of polyimide films are determined, wherein the polyimide films are obtained by reacting 3,3′,4,4′-biphenyltetracarboxylic dianhydride (s-BPDA) and 4, 4′-oxydianiline (ODA) to obtain a polyamic acid, and then adding a chemical imidizing agent (dehydrating agent) to the obtained polyamic acid solution in an amount of 100 mol %, 80 mol %, 60 mol %, 40 mol %, 20 mol % or 0 mol %, and preparing a solution of polyamic acid-polyimide having a pre-imidization degree (pre-ID) of 100%, 80%, 60%, 40%, 20% or 0%, and then heating the solution, and as the result thereof, the coefficient of linear thermal expansion is lower as the pre-imidization degree is higher, and the polyimide film obtained by heating the solution of polyimide having a pre-imidization degree of 100%, that is, the solution of polyimide in which the imidization is fully completed has the lowest coefficient of linear thermal expansion (FIG. 9). However, Non Patent Literature 5 also discloses that the 5% weight loss temperature (T_{5%}) is lower and the heat resistance is reduced as the pre-imidization degree (pre-ID) is higher (p. 4162, right column, the 8-6 line from the bottom).

### CITATION LIST

### Patent Literature

Patent Literature 1: JP-A-2003-168800
Patent Literature 2: WO 2008/146637
Patent Literature 3: JP-A-2002-69179
Patent Literature 4: JP-A-2002-146021
Patent Literature 5: JP-A-2008-31406
Patent Literature 6: WO 2011/099518
Patent Literature 7: WO 2010/113412
Patent Literature 8: JP-A-2005-336243
Patent Literature 9: JP-A-2006-206756
Patent Literature 10: JP-A-H09-185064
Patent Literature 11: JP-A-2006-70096
Patent Literature 12: JP-A-2010-196041
Patent Literature 13: JP-A-2010-18802

### Non Patent Literature

Non Patent Literature 1: KOBUNSHI RONBUNSHU (Japanese Journal of Polymer Science and Technology), Vol. 68, No. 3, p. 127-131
Non Patent Literature 2: European Polymer Journal, Vol. 46, p. 283-297 (2010)
Non Patent Literature 3: Journal of Photopolymer Science and Technology, Vol. 18, p. 307-312 (2005)
Non Patent Literature 4: Journal of Photopolymer Science and Technology, Vol. 24, p. 255-258 (2011)
Non Patent Literature 5: Polymer, Vol. 53, p. 4157-4163 (2012)

### SUMMARY OF INVENTION

### Technical Problem

As described above, in the case of chemical imidization in which a polyimide having a relatively low coefficient of linear thermal expansion may be obtained, the properties of the polyimide may be changed due to the use of a chemical imidizing agent (an acid anhydride such as acetic anhydride, and an amine compound such as pyridine and isoquinoline). On the other hand, in the case of thermal imidization, the coefficient of linear thermal expansion is generally reduced by stretching operation. However, in some applications, or in some processes for producing (forming a film of) polyimide, the coefficient of linear thermal expansion of the polyimide may not be reduced by stretching.

In some applications, it is desired that the coefficient of linear thermal expansion should be reduced without stretching, while maintaining the excellent properties, particularly, in a polyimide formed of a specific diamine component and a specific tetracarboxylic acid component, and having excellent heat resistance, solvent resistance and mechanical properties, which is produced by thermal imidization, and more preferably which also has excellent transparency.

The present invention was made in view of the circumstances as described above, and an object thereof is to provide a polyimide precursor, which is produced by thermal imidization, and from which a polyimide formed of a specific diamine component and a specific tetracarboxylic acid component, and having excellent heat resistance, solvent resistance and mechanical properties, and a low coefficient of linear thermal expansion may be obtained. An object of the present invention is also to provide a polyimide precursor from which a polyimide having a low coefficient of linear thermal expansion, and excellent heat resistance, solvent resistance and mechanical properties, and more preferably also having excellent transparency, may be obtained.

### Solution to Problem

The present invention relates to the following items.

[1] A polyimide precursor consisting of

a repeating unit represented by the following chemical formula (1):

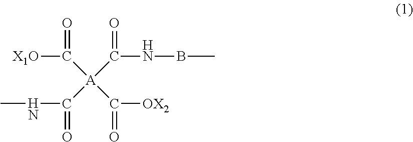

and

a repeating unit represented by the following chemical formula (2):

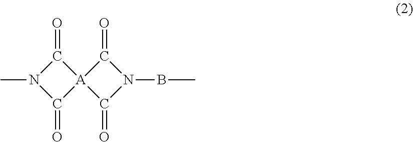

wherein A is a tetravalent group of a tetracarboxylic acid, from which carboxyl groups have been removed; B is a divalent group of a diamine, from which amino groups have been removed; with the proviso that the A group and the B group contained in each repeating unit may be the same as, or different from each other; and X₁ and X₂ are each independently hydrogen, an alkyl group having 1 to 6 carbon atoms, or an alkylsilyl group having 3 to 9 carbon atoms,
wherein

the amount of the repeating unit represented by the chemical formula (2) is 30 mol % or more and 90 mol % or less relative to the total repeating units,

50 mol % or more of the total amount of the B group in the chemical formula (1) and the chemical formula (2) is one or more of divalent group represented by the following chemical formula (3):

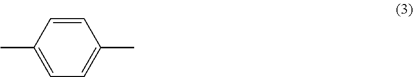

and/or divalent group represented by the following chemical formula (4):
wherein m₁ represents an integer of 1 to 3; represents an integer of 0 to 3;

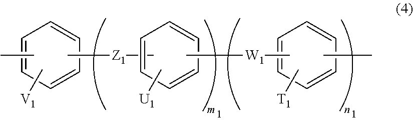

V₁, U₁ and T₁ each independently represent the one selected from the group consisting of hydrogen atom, methyl group and trifluoromethyl group; and Z₁ and W₁ each independently represent direct bond, or the one selected from the group consisting of groups represented by the formulas: —NHCO—, —CONH—, —COO— and —OCO—, and

the polyimide precursor is produced by thermal imidization.

[2] The polyimide precursor as described in [1], wherein the A group in the chemical formula (1) and the chemical formula (2) is one or more of tetravalent group of an alicyclic tetracarboxylic acid from which carboxyl groups have been removed.

[3] The polyimide precursor as described in [1], wherein the A group in the chemical formula (1) and the chemical formula (2) is one or more of tetravalent group of an aromatic tetracarboxylic acid from which carboxyl groups have been removed.

[4] The polyimide precursor as described in any one of [1] to [3], wherein the polyimide precursor comprises a structure represented by the following chemical formula (5):

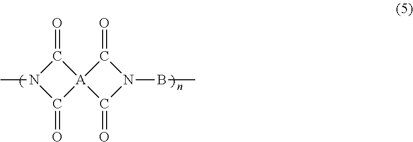

wherein A and B are defined as above; and n is an integer of 1 to 1000.

[5] A varnish comprising the polyimide precursor as described in any one of [1] to [4].

[6] The varnish as described in [5], wherein the varnish does not contain a chemical imidizing agent.

[7] A process for producing the polyimide precursor as described in any one of [1] to [4], comprising steps of:

heating a tetracarboxylic acid component and a diamine component at a temperature of 100° C. or higher in a solvent which does not contain a chemical imidizing agent to thermally react the components, thereby providing a reaction solution which contains a soluble imide compound comprising a repeating unit represented by the chemical formula (2); and

adding a tetracarboxylic acid component and/or a diamine component to the resulting reaction solution, and performing the reaction at a temperature of lower than 100° C. under the condition that the imidization is suppressed, thereby providing the polyimide precursor as described in any one of [1] to [4].

[8] A process for producing the polyimide precursor as described in any one of [1] to [4], comprising steps of;

heating a tetracarboxylic acid component and a diamine component at a temperature of 100° C. or higher in a solvent which does not contain a chemical imidizing agent to thermally react the components, thereby providing a reaction solution which contains a soluble imide compound comprising a repeating unit represented by the chemical formula (2);

isolating the imide compound comprising a repeating unit represented by the chemical formula (2) from the resulting reaction solution; and

adding the isolated imide compound comprising a repeating unit represented by the chemical formula (2) and a tetracarboxylic acid component and/or a diamine component to a solvent which does not contain a chemical imidizing agent, and performing the reaction at a temperature of lower than 100° C. under the condition that the imidization is suppressed, thereby providing the polyimide precursor as described in any one of [1] to [4].

[9] A process for producing the polyimide precursor as described in any one of [1] to [4], comprising steps of;

reacting a tetracarboxylic acid component and a diamine component at a temperature of lower than 100° C. under the condition that the imidization is suppressed in a solvent which does not contain a chemical imidizing agent, thereby providing a reaction solution which contains a (poly)amic acid compound comprising a repeating unit represented by the chemical formula (1); and

heating the reaction solution which contains the (poly)amic acid compound comprising a repeating unit represented by the chemical formula (1) at a temperature of 100° C. or higher to thermally react the compound and convert a part of the repeating unit represented by the chemical formula (1) into a repeating unit represented by the chemical formula (2), thereby providing the polyimide precursor as described in any one of [1] to [4].

[10] A polyimide obtained from the polyimide precursor as described in any one of [1] to [4].

[11] A polyimide obtained by subjecting the varnish as described in [5] or [6] to heat treatment.

[12] A polyimide film obtained by subjecting the varnish as described in [5] or [6] to heat treatment.

[13] A film for TAB, a substrate for electric/electronic components, a wiring board, an insulating film for electric/electronic components, a protective film for electric/electronic components, a substrate for a display, a substrate for a touch panel, or a substrate for a solar battery, comprising the polyimide as described in [10] or [11].

### Advantageous Effects of Invention

According to the present invention, there may be provided a polyimide precursor, which is produced by thermal imidization, and from which a polyimide having excellent heat resistance, solvent resistance and mechanical properties, and a low coefficient of linear thermal expansion may be obtained without stretching. According to the present invention, there may be also provided a polyimide precursor from which a polyimide having a low coefficient of linear thermal expansion, and excellent heat resistance, solvent resistance and mechanical properties, and further having excellent transparency may be obtained. According to the present invention, the coefficient of linear thermal expansion of the polyimide may be reduced without stretching in thermal imidization, while maintaining the excellent properties, and the heat resistance may also be improved.

### BRIEF DESCRIPTION OF DRAWINGS

FIG. 1 is a ¹H-NMR spectrum of the polyimide precursor solution of Comparative Example 3.

FIG. 2 is a ¹H-NMR spectrum of the polyimide precursor solution of Example 19.

### DESCRIPTION OF EMBODIMENTS

The polyimide precursor of the present invention is consisting of a repeating unit of amic acid structure which is represented by the chemical formula (1) and a repeating unit of imide structure which is represented by the chemical formula (2), and the amount of the repeating unit represented by the chemical formula (2) is 30 mol % or more and 90 mol % or less relative to the total repeating units [(repeating unit represented by the chemical formula (1))+(repeating unit represented by the chemical formula (2))]. In other words, the molar ratio of [(repeating unit represented by the chemical formula (2))/{(repeating unit represented by the chemical formula (1))+(repeating unit represented by the chemical formula (2))}] is 30 mol % or more and 90 mol % or less, and the imidization degree is 30% or more and 90% or less.

A polyimide having a lower coefficient of linear thermal expansion may be obtained when the polyimide is produced by imidizing a polyimide precursor wherein the amount of the repeating unit represented by the chemical formula (2) is 30 mol % or more relative to the total repeating units [total amount of the repeating unit represented by the chemical formula (1) and the repeating unit represented by the chemical formula (2)] (the imidization degree is 30% or more), as compared with the case where the polyimide is produced by imidizing a polyimide precursor consisting of only a repeating unit of amic acid structure represented by the chemical formula (1) wherein the imidization degree is 0%. In addition, the heat resistance may also be improved.

Meanwhile, in the polyimide precursor of the present invention, 50 mol % or more, preferably 70 mol % or more, more preferably 80 mol % or more, further preferably 90 mol % or more, particularly preferably 100 mol % of the total diamine component is a diamine component to provide a repeating unit in which the “B” is a divalent group represented by the chemical formula (3) or the chemical formula (4) so as to obtain a polyimide having excellent properties, as described later. The obtained polyimide has excellent solvent resistance, which means that the polyimide is not soluble in an organic solvent. Consequently, a polyimide precursor (or polyimide) may have reduced solubility and the polyimide precursor (or polyimide) may be precipitated, and a polyimide having excellent properties may not be obtained when the amount of the repeating unit represented by the chemical formula (2) is more than 90 mol % relative to the total repeating units [total amount of the repeating unit represented by the chemical formula (1) and the repeating unit represented by the chemical formula (2)] (the imidization degree is more than 90%), and therefore the amount of the repeating unit represented by the chemical formula (2) is limited to 90 mol % or less relative to the total repeating units [total amount of the repeating unit represented by the chemical formula (1) and the repeating unit represented by the chemical formula (2)].

The amount of the repeating unit represented by the chemical formula (2) relative to the total repeating units [total amount of the repeating unit represented by the chemical formula (1) and the repeating unit represented by the chemical formula (2)] (i.e., imidization degree) may be determined by measuring a ¹H-NMR spectrum of the polyimide precursor (polyimide precursor solution) and calculating from the ratio of the integral value of the peak of aromatic proton (7-8.3 ppm) to the integral value of the peak of carboxylic proton (around 12 ppm).

In addition, the polyimide precursor of the present invention may be synthesized, for example, by reacting a tetracarboxylic acid component and a diamine component under the condition that the imidization reaction proceeds (an imide compound is formed), and then adding a tetracarboxylic acid component and/or a diamine component to the resulting reaction solution, and reacting them under the condition that the imidization is suppressed, as described later. In that case, the amount of the repeating unit represented by the chemical formula (2) relative to the total repeating units [total amount of the repeating unit represented by the chemical formula (1) and the repeating unit represented by the chemical formula (2)] (i.e., imidization degree) may be determined from the ratio of the tetracarboxylic acid component and the diamine component reacted under the condition that the imidization reaction proceeds (an imide compound is formed) to the tetracarboxylic acid component and the diamine component reacted under the condition that the imidization is suppressed. Herein, the tetracarboxylic acid component and the diamine component reacted under the condition that the imidization reaction proceeds provide a repeating unit represented by the chemical formula (2), and the tetracarboxylic acid component and the diamine component reacted under the condition that the imidization is suppressed provide a repeating unit represented by the chemical formula (1).

The polymerization degree of the repeating unit of imide structure represented by the chemical formula (2) (i.e., “n” in the chemical formula (5)) may be, but not limited to, an integer of 1 to 1000, for example. The polyimide precursor of the present invention may be synthesized, for example, by the two-step reaction, as described later. In that case, a tetracarboxylic acid component and a diamine component are reacted to obtain a soluble imide compound consisting of a repeating unit represented by the chemical formula (2) firstly. The polymerization degree of the repeating unit of imide structure represented by the chemical formula (2) (i.e., “n” in the chemical formula (5)) may be controlled by adjusting the molar ratio between the tetracarboxylic acid component and the diamine component to be reacted herein. An imide compound in which both terminals are acid anhydride groups or carboxyl groups is obtained when the proportion of the tetracarboxylic acid component is more than the stoichiometric proportion, whereas an imide compound in which both terminals are amino groups is obtained when the proportion of the diamine component is more than the stoichiometric proportion.

For example, when 2 mol of tetracarboxylic dianhydride and 3 mol of diamine are reacted under the condition that the imidization reaction proceeds (an imide compound is formed), a solution which contains an imide compound consisting of a repeating unit represented by the chemical formula (2) is obtained. In this case, an imide compound in which both terminals are amino groups and the polymerization degree (n) is 2 is obtained according to the charge amounts of the tetracarboxylic dianhydride and the diamine. When 10 mol of tetracarboxylic dianhydride and 1 mol of diamine are reacted under the condition that the imidization reaction proceeds (an imide compound is formed), a solution which contains an imide compound consisting of a repeating unit represented by the chemical formula (2) and the tetracarboxylic dianhydride is obtained. In this case, an imide compound in which both terminals are acid anhydride groups or carboxyl groups and the polymerization degree (n) is 1 is obtained according to the charge amounts of the tetracarboxylic dianhydride and the diamine.

The polyimide precursor of the present invention is consisting of a repeating unit of amic acid structure represented by the chemical formula (1) and a repeating unit of imide structure represented by the chemical formula (2), and 50 mol % or more, preferably 70 mol % or more, more preferably 80 mol % or more, further preferably 90 mol % or more, particularly preferably 100 mol % of the total amount of the “B” in the chemical formula (1) and the chemical formula (2) is a divalent group represented by the chemical formula (3) or the chemical formula (4). In other words, the polyimide precursor of the present invention is a polyimide precursor obtained from a tetracarboxylic acid component and a diamine component in which 50 mol % or more, preferably 70 mol % or more, more preferably 80 mol % or more, further preferably 90 mol % or more, particularly preferably 100 mol % thereof is one or more of diamine represented by the chemical formula (3A) as described below and diamine represented by the chemical formula (4A) as described below. When 50 mol % or more, more preferably 70 mol % or more, of the total diamine component is a divalent group represented by the chemical formula (3) or the chemical formula (4), the obtained polyimide has excellent properties such as heat resistance, solvent resistance and mechanical properties.

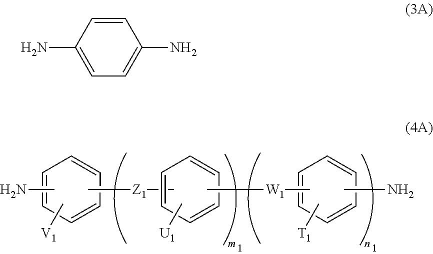

wherein m₁ represents an integer of 1 to 3; Di represents an integer of 0 to 3; V₁, U₁ and T₁ each independently represent the one selected from the group consisting of hydrogen atom, methyl group and trifluoromethyl group; and Z₁ and W₁ each independently represent direct bond, or the one selected from the group consisting of groups represented by the formulas: —NHCO—, —CONH—, —COO— and —OCO—.

In the chemical formula (1) or the chemical formula (2), less than 50 mol % of the “B” may be one, or two or more types of divalent groups represented by the chemical formula (3) or the chemical formula (4) and not less than 50 mol % of the “B” may be one or more types of other groups, on the condition that 50 mol % or more of the total amount of the “B” in the chemical formula (1) and the chemical formula (2) is one, or two or more types of divalent groups represented by the chemical formula (3) or the chemical formula (4).

In one embodiment, in view of the desired properties of the obtained polyimide, it may be preferred that preferably 80 mol % or less, or less than 80 mol %, more preferably 90 mol % or less, or less than 90 mol % of the total amount of the “B” in the chemical formula (1) and the chemical formula (2) is a divalent group represented by the chemical formula (3) or the chemical formula (4). For example, other aromatic or aliphatic diamines [diamine component other than the diamine represented by the chemical formula (3A) and the diamine represented by the chemical formula (4A)], including aromatic diamine containing a plurality of aromatic rings which are linked to each other by ether bond (—O—) such as 4,4′-bis(4-aminophenoxy)biphenyl, may be used preferably in an amount of not more than 20 mol %, more preferably less than 20 mol %, more preferably not more than 10 mol %, more preferably less than 10 mol %, relative to 100 mol % of the total diamine component.

Examples of the diamine component to provide a repeating unit in which the “B” is a divalent group represented by the chemical formula (3) or the chemical formula (4) [the diamine represented by the chemical formula (3A) and the diamine represented by the chemical formula (4A)] include p-phenylenediamine (PPD), 4,4′-diaminobenzanilide (DABAN), 2,2′-bis(trifluoromethyl)benzidine (TFMB), 9,9-bis(4-aminophenyl)fluorene (FDA), benzidine, 3,3′-diamino-biphenyl, 3,3′-bis(trifluoromethyl)benzidine, 3,3′-diaminobenzanilide, o-tolidine, m-tolidine, N,N′-bis(4-aminophenyl)terephthalamide, N,N′-p-phenylene bis(p-aminobenzamide), 4-aminophenyl-4-aminobenzoate, bis(4-aminophenyl)terephthalate, biphenyl-4,4′-dicarboxylic acid bis(4-aminophenyl)ester, p-phenylene bis(p-aminobenzoate), bis(4-aminophenyl)-[1,1′-biphenyl]-4,4′-dicarboxylate, and [1,1′-biphenyl]-4,4′-diyl, bis(4-aminobenzoate). These may be used alone or in combination of a plurality of types.

The diamine component preferably comprises p-phenylenediamine, 4,4′-diaminobenzanilide, 2,2′-bis(trifluoromethyl)benzidine, benzidine, o-tolidine, m-tolidine, N,N′-bis(4-aminophenyl)terephthalamide, N,N′-p-phenylene bis(p-aminobenzamide), 4-aminophenyl-4-aminobenzoate, bis(4-aminophenyl)terephthalate, biphenyl-4,4′-dicarboxylic acid bis(4-aminophenyl)ester, p-phenylene bis(p-aminobenzoate), bis(4-aminophenyl)-[1,1′-biphenyl]-4,4′-dicarboxylate, or [1,1′-biphenyl]-4,4′-diyl, bis(4-aminobenzoate), and particularly preferably comprises 4,4′-diaminobenzanilide. In other words, in the polyimide precursor of the present invention, at least part of the “B” in the chemical formula (1) and/or the chemical formula (2) is particularly preferably a divalent group represented by the chemical formula (6-1) or (6-2) as described below. The amount thereof may be preferably, but not limited to, 30 mol % or more relative to the total amount of the “B” in the chemical formula (1) and the chemical formula (2).

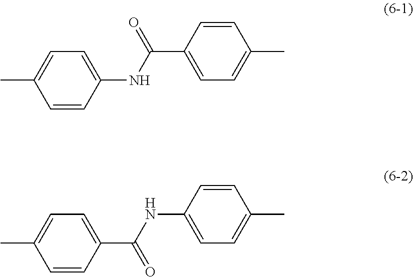

In the present invention, a diamine component other than the diamine component to provide a repeating unit in which the “B” is a divalent group represented by the chemical formula (3) or the chemical formula (4) [the diamine represented by the chemical formula (3A) and the diamine represented by the chemical formula (4A)] may be used in an amount of less than 50 mol %.

Examples of the diamine component include aromatic diamines such as m-phenylenediamine, 2-methylbenzene-1,4-diamine, 2-(trifluoromethyl)benzene-1,4-diamine, 9,9-bis(4-aminophenyl)fluorene (FDA), 4,4′-oxydianiline, 3,4′-oxydianiline, 3,3′-oxydianiline, p-methylene bis(phenylenediamine), 1,3-bis(4-aminophenoxy)benzene, 1,3-bis(3-aminophenoxy)benzene, 1,4-bis(4-aminophenoxy)benzene, 2,2-bis[4-(4-aminophenoxy)phenyl]hexafluoropropane, 2,2-bis(4-aminophenyl)hexafluoropropane, bis(4-aminophenyl)sulfone, 3,3-bis((aminophenoxy)phenyl)propane, 2,2-bis(3-amino-4-hydroxyphenyl)hexafluoropropane, bis((aminophenoxy)diphenyl)sulfone, bis(4-(4-aminophenoxy)diphenyl)sulfone, bis(4-(3-aminophenoxy)diphenyl)sulfone, octafluorobenzidine, 3,3′-dimethoxy-4,4′-diaminobiphenyl, 3,3′-dichloro-4,4′-diaminobiphenyl, 3,3′-difluoro-4,4′-diaminobiphenyl, 4,4′-bis(4-aminophenoxy)biphenyl and 4,4′-bis(3-aminophenoxy)biphenyl; and alicyclic diamines such as 1,4-diaminocyclohexane, 1,4-diamino-2-methylcyclohexane, 1,4-diamino-2-ethylcyclohexane, 1,4-diamino-2-n-propylcyclohexane, 1,4-diamino-2-isopropylcyclohexane, 1,4-diamino-2-n-butylcyclohexane, 1,4-diamino-2-isobutylcyclohexane, 1,4-diamino-2-sec-butylcyclohexane, 1,4-diamino-2-tert-butylcyclohexane and 1,2-diaminocyclohexane. These may be used alone or in combination of a plurality of types.

As described above, in one embodiment, such a diamine component other than the diamine represented by the chemical formula (3A) and the diamine represented by the chemical formula (4A), for example, an aromatic diamine containing a plurality of aromatic rings which are linked to each other by ether bond (—O—) such as 4,4′-bis(4-aminophenoxy)biphenyl, may be preferably used preferably in an amount of not more than 20 mol %, more preferably less than 20 mol %, more preferably not more than 10 mol %, more preferably less than 10 mol %.

The tetracarboxylic acid component to be used in the present invention is not limited, and may be an alicyclic tetracarboxylic acid component or may be an aromatic tetracarboxylic acid component. The tetracarboxylic acid component includes tetracarboxylic acid, and tetracarboxylic acid derivatives including tetracarboxylic dianhydride, tetracarboxylic acid silyl ester, tetracarboxylic acid ester, and tetracarboxylic acid chloride.

Examples of the tetracarboxylic acid component include alicyclic tetracarboxylic acid components (alicyclic tetracarboxylic dianhydrides) such as norbornane-2-spiro-α-cyclopentanone-α′-spiro-2″-norbornane-5,5″,6,6″-tetracarboxylic dianhydride (CpODA), (4arH,8acH)-decahydro-1t,4t:5c,8c-dimethanonaphthalene-2t,3t,6c,7c-tetracarboxylic dianhydride (DNDAxx), (4arH,8acH)-decahydro-1t,4t:5c,8c-dimethanonaphthalene-2c,3c,6c,7c-tetracarboxylic dianhydride, cyclohexane-1,2,4,5-tetracarboxylic acid, 1,2,3,4-cyclobutane tetracarboxylic dianhydride, [1,1′-bi(cyclohexane)]-3,3′,4,4′-tetracarboxylic acid, [1,1′-bi(cyclohexane)]-2,3,3′,4′-tetracarboxylic acid, [1,1′-bi(cyclohexane)]-2,2′,3,3′-tetracarboxylic acid, 4,4′-methylene bis(cyclohexane-1,2-dicarboxylic acid), 4,4′-(propane-2,2-diyl)bis(cyclohexane-1,2-dicarboxylic acid), 4,4′-oxy bis(cyclohexane-1,2-dicarboxylic acid), 4,4′-thio bis(cyclohexane-1,2-dicarboxylic acid), 4,4′-sulfonyl bis(cyclohexane-1,2-dicarboxylic acid), 4,4′-(dimethylsilanediyl)bis(cyclohexane-1,2-dicarboxylic acid), 4,4′-(tetrafluoropropane-2,2-diyl)bis(cyclohexane-1,2-dicarboxylic acid), octahydropentalene-1,3,4,6-tetracarboxylic acid, bicyclo[2.2.1]heptane-2,3,5,6-tetracarboxylic acid, 6-(carboxymethyl)bicyclo[2.2.1]heptane-2,3,5-tricarboxylic acid, bicyclo[2.2.2]octane-2,3,5,6-tetracarboxylic acid, bicyclo[2.2.2]octa-5-ene-2,3,7,8-tetracarboxylic acid, tricyclo[4.2.2.02,5]decane-3,4,7,8-tetracarboxylic acid, tricyclo[4.2.2.02,5]deca-7-ene-3,4,9,10-tetracarboxylic acid and 9-oxatricyclo[4.2.1.02,5]nonane-3,4,7,8-tetracarboxylic acid, and derivatives thereof; and aromatic tetracarboxylic acid components (aromatic tetracarboxylic dianhydrides) such as 3,3′,4,4′-biphenyl tetracarboxylic dianhydride (s-BPDA), pyromellitic dianhydride, 2,3,3′,4′-biphenyl tetracarboxylic dianhydride, 3,3′,4,4′-benzophenone tetracarboxylic dianhydride, 2,2-bis(3,4-dicarboxyphenyl)hexafluoropropane dianhydride, bis(3,4-dicarboxyphenyl)methane dianhydride, 4,4′-oxydiphthalic dianhydride, bis(3,4-dicarboxyphenyl)sulfone dianhydride, m-terphenyl-3,4,3′,4′-tetracarboxylic dianhydride, p-terphenyl-3,4,3′,4′-tetracarboxylic dianhydride, bis(3,4-dicarboxyphenyl)sulfide dianhydride, p-phenylene bis(trimellitic monoester anhydride), ethylene bis(trimellitic monoester anhydride), bisphenol A bis(trimellitic monoester anhydride), 2,2-bis(3,4-dicarboxyphenyl)-1,1,1,3,3,3-hexafluoropropane dianhydride, 2,2-bis(2,3-dicarboxyphenyl)-1,1,1,3,3,3-hexafluoropropane dianhydride, 1,2,5,6-naphthalene tetracarboxylic dianhydride, 2,3,6,7-naphthalene tetracarboxylic dianhydride, 1,4,5,8-naphthalene tetracarboxylic dianhydride, 2,2-bis{4-[4-(1,2-dicarboxy)phenoxy]phenyl}propane dianhydride, 2,2-bis{4-[3-(1,2-dicarboxy)phenoxy]phenyl}propane dianhydride, bis{4-[4-(1,2-dicarboxy)phenoxy]phenyl}ketone dianhydride, bis{4-[3-(1,2-dicarboxy)phenoxy]phenyl}ketone dianhydride, 4,4′-bis[4-(1,2-dicarboxy)phenoxy]biphenyl dianhydride, 4,4′-bis[3-(1,2-dicarboxy)phenoxy]biphenyl dianhydride, bis{4-[4-(1,2-dicarboxy)phenoxy]phenyl}ketone dianhydride, bis{4-[3-(1,2-dicarboxy)phenoxy]phenyl}ketone dianhydride, bis{4-[4-(1,2-dicarboxy)phenoxy]phenyl}sulfone dianhydride, bis{4-[3-(1,2-dicarboxy)phenoxy]phenyl}sulfone dianhydride, bis{4-[4-(1,2-dicarboxy)phenoxy]phenyl}sulfide dianhydride and bis{4-[3-(1,2-dicarboxy)phenoxy]phenyl}sulfide dianhydride. These may be used alone or in combination of a plurality of types. Additionally, one or more aromatic tetracarboxylic acid components and one or more alicyclic tetracarboxylic acid components may be used in combination.

In order to obtain a polyimide having excellent heat resistance, an aromatic tetracarboxylic acid component is preferably used as the tetracarboxylic acid component. In other words, the “A” in the chemical formula (1) and the chemical formula (2) is preferably a tetravalent group of an aromatic tetracarboxylic acid from which carboxyl groups have been removed. As the tetracarboxylic acid component, 3,3′,4,4′-biphenyl tetracarboxylic dianhydride (s-BPDA), pyromellitic dianhydride, 3,3′,4,4′-benzophenone tetracarboxylic dianhydride, 2,2-bis(3,4-dicarboxyphenyl)hexafluoropropane dianhydride, 4,4′-oxydiphthalic dianhydride, bis(3,4-dicarboxyphenyl)sulfone dianhydride, or p-terphenyl-3,4,3′,4′-tetracarboxylic dianhydride is particularly preferably used.

In order to obtain a polyimide having excellent transparency, an alicyclic tetracarboxylic acid component is preferably used as the tetracarboxylic acid component. In other words, the “A” in the chemical formula (1) and the chemical formula (2) is preferably a tetravalent group of an alicyclic tetracarboxylic acid from which carboxyl groups have been removed. As the tetracarboxylic acid component, norbornane-2-spiro-α-cyclopentanone-α′-spiro-2″-norbornane-5,5″,6,6″-tetracarboxylic dianhydride, or (4arH,8acH)-decahydro-1t,4t:5c,8c-dimethanonaphthalene-2t,3t,6c,7c-tetracarboxylic dianhydride is particularly preferably used.

X₁ and X₂ in the chemical formula (1) are each independently hydrogen, an alkyl group having 1 to 6 carbon atoms, preferably having 1 to 3 carbon atoms (more preferably methyl or ethyl), or an alkylsilyl group having 3 to 9 carbon atoms (more preferably trimethylsilyl or t-butyldimethylsilyl).

As for X₁ and X₂, the types of the functional groups and the introduction ratio of the functional groups may be changed by the production method as described later. When an alkyl group or an alkylsilyl group is introduced, each of X₁ and X₂ may be converted into an alkyl group or an alkylsilyl group in a ratio of 25% or more, preferably 50% or more, more preferably 75% or more, although the introduction ratio of the functional groups is not limited thereto.

According to the chemical structure X₁ and X₂ have, the polyimide precursors of the present invention may be classified into 1) partially-imidized polyamic acid (X₁ and X₂ are hydrogen), 2) partially-imidized polyamic acid ester (at least part of X₁ and X₂ is alkyl group), and 3) 4) partially-imidized polyamic acid silyl ester (at least part of X₁ and X₂ is alkylsilyl group). Each class of the polyimide precursors of the present invention may be produced by the production methods as described below. However, the method for producing the polyimide precursor of the present invention is not limited to the following production methods.

1) Partially-Imidized Polyamic Acid

The polyimide precursor (partially-imidized polyamic acid) of the present invention may be produced, for example, by thermal imidization as follows.

Firstly, a reaction solution which contains a soluble imide compound consisting of a repeating unit represented by the chemical formula (2) is obtained by heating a tetracarboxylic dianhydride as a tetracarboxylic acid component and a diamine component in a solvent which does not contain a chemical imidizing agent to thermally react the components (first step). In the polyimide precursor of the present invention, the amount of the repeating unit represented by the chemical formula (2) is 30 mol % or more and 90 mol % or less relative to the total repeating units [total amount of the repeating unit represented by the chemical formula (1) and the repeating unit represented by the chemical formula (2)] (that is, the imidization degree is 30% or more and 90% or less). Accordingly, the ratio of the tetracarboxylic acid component or the diamine component to be reacted in this step is preferably 30 mol % to 90 mol % relative to the total amount of the tetracarboxylic acid component or the diamine component to be reacted in the first step and in the subsequent second step. In other words, the ratio of either the tetracarboxylic acid component or the diamine component to be added to the solvent in the first step is preferably 30 mol % to 90 mol % relative to the total amount of the tetracarboxylic acid component or the diamine component to be reacted in the first step and in the subsequent second step. The imide compound obtained in this step may comprise a repeating unit represented by the chemical formula (1), on the condition that the amount of the repeating unit represented by the chemical formula (2) is 30 mol % or more and 90 mol % or less relative to the total repeating units [total amount of the repeating unit represented by the chemical formula (1) and the repeating unit represented by the chemical formula (2)] in the finally-obtained polyimide precursor (that is, the imidization degree is 30% or more and 90% or less).

Additionally, the molar ratio of the tetracarboxylic acid component to the diamine component to be reacted herein may be appropriately selected according to the desired polymerization degree of the imide compound, that is, the polymerization degree of the repeating unit of imide structure represented by the chemical formula (2) in the polyimide precursor ([“n” in the chemical formula (5)].

In the first step, a tetracarboxylic dianhydride as a tetracarboxylic acid component and a diamine component are reacted under the condition that the imidization reaction proceeds, specifically, at a temperature of 100° C. or higher. More specifically, a soluble imide compound may be obtained by dissolving a diamine in a solvent, adding a tetracarboxylic dianhydride to the resulting solution gradually while stirring the solution, and then stirring the solution at a temperature of 100° C. or higher, preferably 120° C. to 250° C., for 0.5 to 72 hours. The sequence of the addition of the diamine and the tetracarboxylic dianhydride may be reversed.

In the present invention, the polyimide precursor is produced by thermal imidization, and therefore a chemical imidizing agent is not used. Herein, the chemical imidizing agent includes an acid anhydride (dehydrating agent) such as acetic anhydride, and an amine compound (catalyst) such as pyridine and isoquinoline.

In the soluble imide compound consisting of a repeating unit represented by the chemical formula (2), both terminals may be acid anhydride groups or carboxyl groups, or may be amino groups.

Subsequently, the polyimide precursor of the present invention is obtained by adding a tetracarboxylic acid component and/or a diamine component to the reaction solution obtained in the first step which contains the soluble imide compound, and performing the reaction under the condition that the imidization is suppressed (second step). In the second step, a tetracarboxylic acid component and/or a diamine component are added thereto such that the molar ratio between the total amount of the tetracarboxylic acid component and the total amount of the diamine component to be reacted in the first step and the second step is substantially equimolar, and preferably the molar ratio of the diamine component to the tetracarboxylic acid component [molar number of the diamine component/molar number of the tetracarboxylic acid component] is 0.90 to 1.10, more preferably 0.95 to 1.05.

In the second step, the reaction is performed under the condition that the imidization is suppressed, specifically, at a temperature of lower than 100° C. More specifically, the polyimide precursor of the present invention may be obtained by adding a diamine to the reaction solution obtained in the first step which contains the soluble imide compound, and stirring the solution at a temperature of lower than 100° C., preferably −20° C. to 80° C., for 1 to 72 hours, and then adding a tetracarboxylic dianhydride to the resulting solution, and stirring the solution at a temperature of lower than 100° C., preferably −20° C. to 80° C., for 1 to 72 hours. The sequence of the addition of the diamine and the tetracarboxylic dianhydride may be reversed, and the diamine and the tetracarboxylic dianhydride may be added thereto simultaneously. Additionally, only the diamine is added thereto in the case where all of the tetracarboxylic acid component to be reacted is added to the solvent in the first step, and only the tetracarboxylic dianhydride is added thereto in the case where all of the diamine component to be reacted is added to the solvent in the first step.

Although the imidization may proceed in the second step, the reaction temperature and the reaction time should be appropriately selected such that the amount of the repeating unit represented by the chemical formula (2) is 30 mol % or more and 90 mol % or less relative to the total repeating units [total amount of the repeating unit represented by the chemical formula (1) and the repeating unit represented by the chemical formula (2)] in the finally-obtained polyimide precursor (that is, the imidization degree is 30% or more and 90% or less).

In the first step, the repeating unit of imide structure represented by the chemical formula (2) is mainly formed, and in the second step, the repeating unit of amic acid structure represented by the chemical formula (1) is mainly formed. A polyimide having a lower coefficient of linear thermal expansion may be obtained when the tetracarboxylic acid component and the diamine component to provide a polymer having a great coefficient of linear thermal expansion are reacted in the first step and converted into the repeating unit of imide structure.

As for the solvent used in the production of the polyimide precursor, aprotic solvents such as N,N-dimethylformamide, N,N-dimethylacetamide, 1-methyl-2-pyrrolidone, 1-ethyl-2-pyrrolidone, 1,1,3,3-tetramethylurea, 1,3-dimethyl-2-imidazolidinone and dimethyl sulfoxide are preferred, for example, and N,N-dimethylacetamide and 1-methyl-2-pyrrolidone are particularly preferred. However, any solvent may be used without any trouble on the condition that the starting monomer components and the formed polyimide precursor can be dissolved in the solvent, and the solvent is not limited to the structure. Examples of the solvent preferably employed include amide solvents such as N,N-dimethylformamide, N,N-dimethylacetamide and 1-methyl-2-pyrrolidone; cyclic ester solvents such as γ-butyrolactone, γ-valerolactone, δ-valerolactone, γ-caprolactone, ε-caprolactone and α-methyl-γ-butyrolactone; carbonate solvents such as ethylene carbonate and propylene carbonate; glycol solvents such as triethylene glycol; phenol solvents such as m-cresol, p-cresol, 3-chlorophenol and 4-chlorophenol; acetophenone, 1,3-dimethyl-2-imidazolidinone, sulfolane, and dimethylsulfoxide. In addition, other common organic solvents, namely, phenol, o-cresol, butyl acetate, ethyl acetate, isobutyl acetate, propyleneglycol methyl acetate, ethyl cellosolve, butyl cellosolve, 2-methyl cellosolve acetate, ethyl cellosolve acetate, butyl cellosolve acetate, tetrahydrofuran, dimethoxyethane, diethoxyethane, dibutyl ether, diethylene glycol dimethyl ether, methyl isobutyl ketone, diisobutyl ketone, cyclopentanone, cyclohexanone, methyl ethyl ketone, acetone, butanol, ethanol, xylene, toluene, chlorobenzene, turpentine, mineral spirits, petroleum naphtha-based solvents, and the like may be used. These may be used in combination of a plurality of types.

The polyimide precursor of the present invention may also be obtained by isolating the soluble imide compound consisting of a repeating unit represented by the chemical formula (2) from the reaction solution obtained after the first step, and in the second step, adding the isolated imide compound consisting of a repeating unit represented by the chemical formula (2) and a tetracarboxylic acid component and/or a diamine component to a solvent, and performing the reaction under the condition that the imidization is suppressed. In this case, it is preferred that the both terminals are amino groups in the imide compound obtained in the first step. That is because when the both terminals are acid anhydride groups, the acid anhydride may undergo ring-opening to be converted into carboxylic acid, and the like during the isolation.

The isolation of the soluble imide compound may be performed, for example, by dropping or mixing the reaction solution obtained in the first step, which contains the soluble imide compound, into a poor solvent such as water to precipitate (reprecipitate) the imide compound.

In this case, the reaction conditions in the first step and the second step are the same as described above.

The polyimide precursor (partially-imidized polyamic acid) of the present invention may also be produced as follows.

Firstly, a reaction solution which contains a (poly)amic acid compound consisting of a repeating unit represented by the chemical formula (1) is obtained by reacting a tetracarboxylic dianhydride as a tetracarboxylic acid component and a diamine component under the condition that the imidization is suppressed, specifically, at a temperature of lower than 100° C. in a solvent which does not contain a chemical imidizing agent (first step). More specifically, a reaction solution is obtained by dissolving a diamine in a solvent which does not contain a chemical imidizing agent, adding a tetracarboxylic dianhydride to the resulting solution gradually while stirring the solution, and stirring the solution at a temperature of lower than 100° C., preferably −20° C. to 80° C., for 1 to 72 hours, and then adding a tetracarboxylic dianhydride to the resulting solution, and stirring the solution at a temperature of lower than 100° C., preferably −20° C. to 80° C., for 1 to 72 hours. The sequence of the addition of the diamine and the tetracarboxylic dianhydride may be reversed, and the diamine and the tetracarboxylic dianhydride may be added thereto simultaneously.

In the first step, a tetracarboxylic dianhydride as a tetracarboxylic acid component and a diamine component are preferably reacted in a substantially equimolar amount, preferably in the molar ratio of the diamine component to the tetracarboxylic acid component [molar number of the diamine component/molar number of the tetracarboxylic acid component] of 0.90 to 1.10, more preferably 0.95 to 1.05.

Additionally, the imidization may partially proceed and the (poly)amic acid compound obtained in the first step may comprise a repeating unit represented by the chemical formula (2). However, the amount of the repeating unit represented by the chemical formula (2) is less than 90 mol % relative to the total repeating units [total amount of the repeating unit represented by the chemical formula (1) and the repeating unit represented by the chemical formula (2)] (the imidization degree is less than 90%).

Subsequently, the polyimide precursor of the present invention, in which the amount of the repeating unit represented by the chemical formula (2) is 30 mol % or more and 90 mol % or less relative to the total repeating units [(repeating unit represented by the chemical formula (1))+(repeating unit represented by the chemical formula (2))], is obtained by heating the reaction solution obtained in the first step, which contains the (poly)amic acid compound, under the condition that the imidization reaction proceeds, specifically, at a temperature of 100° C. or higher to thermally react the compound and convert a part of the repeating unit represented by the chemical formula (1) into a repeating unit represented by the chemical formula (2) (second step). More specifically, the polyimide precursor of the present invention may be obtained by stirring the reaction solution at a temperature of 100° C. or higher, preferably 120° C. or higher, more preferably 150° C. to 250° C., for 5 minutes to 72 hours.

In the second step, the reaction temperature and the reaction time should be appropriately selected such that the amount of the repeating unit represented by the chemical formula (2) is 30 mol % or more and 90 mol % or less relative to the total repeating units [total amount of the repeating unit represented by the chemical formula (1) and the repeating unit represented by the chemical formula (2)] in the finally-obtained polyimide precursor (that is, the imidization degree is 30% or more and 90% or less). Although the reaction temperature and the reaction time are within the above-mentioned range, the amount of the repeating unit represented by the chemical formula (2) is sometimes 90 mol % or more relative to the total repeating units [(repeating unit represented by the chemical formula (1))+(repeating unit represented by the chemical formula (2))] when the reaction temperature is relatively high and the reaction time is relatively long.

In this case, the same solvent as described above may be used as the solvent used in the production of the polyimide precursor.

2) Partially-Imidized Polyamic Acid Ester

A diester dicarboxylic acid dichloride may be obtained by reacting a tetracarboxylic dianhydride and an arbitrary alcohol to provide a diester dicarboxylic acid, and then reacting the diester dicarboxylic acid and a chlorinating agent (thionyl chloride, oxalyl chloride, and the like). The polyimide precursor may be obtained by stirring the diester dicarboxylic acid chloride and a diamine at a temperature of −20° C. to 120° C., preferably −5° C. to 80° C., for 1 hour to 72 hours. When they are reacted at a temperature of 80° C. or higher, the molecular weight may vary depending on the temperature history in the polymerization and the imidization may proceed by heat, and therefore the polyimide precursor may not be stably produced. In addition, the polyimide precursor may also be easily obtained by dehydrating/condensing a diester dicarboxylic acid and a diamine by the use of a phosphorus-based condensing agent, a carbodiimide condensing agent, or the like.

The polyimide precursor obtained by the method is stable, and therefore the polyimide precursor may be subjected to purification, for example, reprecipitation in which a solvent such as water and alcohols is added thereto.

The partially-imidized polyamic acid ester may be obtained by heating the obtained polyimide precursor at a temperature of 80° C. or higher to thermally react and partially imidize the compound.

3) Partially-Imidized Polyamic Acid Silyl Ester (Indirect Method)

A silylated diamine may be obtained by reacting a diamine and a silylating agent in advance. The silylated diamine may be purified by distillation, or the like, as necessary. And then, the polyimide precursor may be obtained by dissolving the silylated diamine in a dehydrated solvent, adding a tetracarboxylic dianhydride to the resulting solution gradually while stirring the solution, and then stirring the solution at a temperature of 0° C. to 120° C., preferably 5° C. to 80° C., for 1 hour to 72 hours. When they are reacted at a temperature of 80° C. or higher, the molecular weight may vary depending on the temperature history in the polymerization and the imidization may proceed by heat, and therefore the polyimide precursor may not be stably produced.

As for the silylating agent to be used herein, the use of a silylating agent containing no chlorine is preferred because it is unnecessary to purify the silylated diamine. Examples of the silylating agent containing no chlorine atom include N,O-bis(trimethylsilyl)trifluoroacetamide, N,O-bis(trimethylsilyl)acetamide, and hexamethyldisilazane. Among them, N,O-bis(trimethylsilyl)acetamide, and hexamethyldisilazane are particularly preferred; because they contain no fluorine atom and are inexpensive.

In addition, in the silylation reaction of diamine, an amine catalyst such as pyridine, piperidine and triethylamine may be used so as to accelerate the reaction. The catalyst may be used, as it is, as a catalyst for the polymerization of the polyimide precursor.

The partially-imidized polyamic acid silyl ester may be obtained by heating the obtained polyimide precursor at a temperature of 80° C. or higher to thermally react and partially imidize the compound.

4) Partially-Imidized Polyamic Acid Silyl Ester (Direct Method)

The partially-imidized polyamic acid silyl ester may be obtained by mixing a polyamic acid solution obtained by the method 1) and a silylating agent, and then stirring the resulting mixture at a temperature of 0° C. to 120° C., preferably 5° C. to 80° C., for 1 hour to 72 hours.

As for the silylating agent to be used herein, the use of a silylating agent containing no chlorine is preferred because it is unnecessary to purify the silylated polyamic acid, or the obtained polyimide. Examples of the silylating agent containing no chlorine atom include N,O-bis(trimethylsilyl)trifluoroacetamide, N,O-bis(trimethylsilyl)acetamide, and hexamethyldisilazane. Among them, N,O-bis(trimethylsilyl)acetamide, and hexamethyldisilazane are particularly preferred, because they contain no fluorine atom and are inexpensive.

The polyimide precursor may also be obtained by reacting a tetracarboxylic dianhydride as a tetracarboxylic acid component and a diamine component under the condition that the imidization is suppressed, specifically, at a temperature of lower than 100° C., and mixing the resulting reaction solution and a silylating agent, and then stirring the resulting mixture at a temperature of 0° C. to 120° C., preferably 5° C. to 80° C., for 1 hour to 72 hours. The partially-imidized polyamic acid silyl ester may be obtained by heating the obtained polyimide precursor at a temperature of 80° C. or higher to thermally react and partially imidize the compound.

All of the production methods as described above may be suitably performed in a solvent, and as a consequence a varnish of the polyimide precursor (polyimide precursor solution or solution composition) of the present invention may be easily obtained. As necessary, the solvent may be removed from or added to the polyimide precursor solution or solution composition obtained by the production method, and a desired component may be added to the polyimide precursor solution or solution composition.

In the present invention, although the logarithmic viscosity of the polyimide precursor is not limited thereto, the logarithmic viscosity of the polyimide precursor in a solution of the solvent used in the polymerization at a concentration of 0.5 g/dL at 30° C. may be preferably 0.2 dL/g or more, preferably 0.5 dL/g or more. When the logarithmic viscosity is 0.2 dL/g or more, the molecular weight of the polyimide precursor is high, and therefore the obtained polyimide may have excellent mechanical strength and heat resistance.

In the present invention, the varnish of the polyimide precursor comprises at least the polyimide precursor of the present invention and a solvent. It is preferred that the total amount of the tetracarboxylic acid component and the diamine component is 5 mass % or more, preferably 10 mass % or more, more preferably 15 mass % or more, relative to the total amount of the solvent, the tetracarboxylic acid component and the diamine component. Additionally, it is generally preferred that the total amount is 60 mass % or less, preferably 50 mass % or less. When the concentration, which is approximate to the concentration of the solid content based on the polyimide precursor, is too low, it may be difficult to control the thickness of the obtained polyimide film in the production of polyimide film, for example.

The solvent used for the varnish of the polyimide precursor of the present invention is not limited and any solvent may be used without any trouble, on the condition that the polyimide precursor can be dissolved in the solvent. Examples of the solvent used for the varnish of the polyimide precursor include the same solvents as described above as the solvent used in the production of the polyimide precursor. Additionally, the solvent may be used in combination of a plurality of types.

In the present invention, although the viscosity (rotational viscosity) of the varnish of the polyimide precursor is not limited thereto, the rotational viscosity, which is measured with an E-type rotational viscometer at a temperature of 25° C. and at a shearing speed of 20 sec⁻¹, may be preferably 0.01 to 1000 Pa·sec, more preferably 0.1 to 100 Pa·sec. In addition, thixotropy may be imparted, as necessary. When the viscosity is within the above-mentioned range, the varnish is easy to handle during the coating or the film formation, and the varnish is less repelled and has excellent leveling property, and therefore a good film may be obtained.

As necessary, an anti-oxidizing agent, a filler, a dye, a pigment, a coupling agent such as a silane coupling agent, a primer, a flame retardant, a defoaming agent, a leveling agent, a rheology control agent (flow-promoting agent), a releasing agent, and the like may be added to the varnish of the polyimide precursor of the present invention. It is preferred that the varnish of the polyimide precursor of the present invention does not contain a chemical imidizing agent.

The polyimide of the present invention is a polyimide obtained from the polyimide precursor of the present invention as described above, and may be suitably produced by the dehydration/ring closure reaction (imidization reaction) of the polyimide precursor of the present invention. In the present invention, any known thermal imidization method may be suitably applied without limitation. Preferred examples of the form of the obtained polyimide include a film, a laminate of a polyimide film and another substrate, a coating film, a powder, a bead, a molded article, and a foamed article.

As necessary, an inorganic particle such as silica may be mixed into the polyimide obtained from the polyimide precursor of the present invention, that is, the polyimide of the present invention. Examples of the method for mixing inorganic particles therein include, but not limited to, a method in which an inorganic particle is dispersed in a polymerization solvent, and then a polyimide precursor is polymerized in the solvent; a method in which a polyimide precursor solution and an inorganic particle are mixed; and a method in which a polyimide precursor solution and an inorganic particle dispersion are mixed.

The polyimide of the present invention (the polyimide obtained from the polyimide precursor of the present invention) may have preferably, but not limited to, a coefficient of linear thermal expansion from 50° C. to 200° C. of 40 ppm/K or less, more preferably 35 ppm/K or less, more preferably 30 ppm/K or less, particularly preferably 25 ppm/K or less, when the polyimide is formed into a film, and have a very low coefficient of linear thermal expansion. When the coefficient of linear thermal expansion is great, the difference in the coefficient of linear thermal expansion between the polyimide and a conductive material such as a metal is great, and therefore a trouble such as an increase in warpage may occur during the formation of a circuit board.

In some applications, it is desired that the polyimide should have excellent optical transparency. The polyimide of the present invention (the polyimide obtained from the polyimide precursor of the present invention) may have preferably, but not limited to, a total light transmittance (average light transmittance at wavelengths of 380 nm to 780 nm) of 80% or more, more preferably 83% or more, more preferably 85% or more, particularly preferably 88% or more, in the form of a film having a thickness of 10 μm. When the total light transmittance is low, the light source must be bright, and therefore a problem of more energy required, or the like may arise in the case where the polyimide is used in display application, or the like.

Additionally, the polyimide of the present invention (the polyimide obtained from the polyimide precursor of the present invention) may have preferably, but not limited to, a light transmittance at a wavelength of 400 nm of 65% or more, more preferably 70% or more, more preferably 75% or more, particularly preferably 80% or more, in the form of a film having a thickness of 10 μm.

In some applications, properties other than optical transparency are required, and the total light transmittance in the form of a film having a thickness of 10 μm and the light transmittance at a wavelength of 400 nm in the form of a film having a thickness of 10 μm may not be within the above-mentioned range.

As for a film formed of the polyimide of the present invention, the thickness of the film is preferably 1 μm to 250 μm, more preferably 1 μm to 150 μm, more preferably 1 μm to 50 μm, particularly preferably 1 μm to 30 μm, although it varies depending on the intended use. When the polyimide film is too thick, the light transmittance may be low in the case where the polyimide film is used in applications where light passes through the polyimide film.

The polyimide of the present invention (the polyimide obtained from the polyimide precursor of the present invention) may have preferably, but not limited to, a 5% weight loss temperature of more than 470° C., more preferably 480° C. or more, more preferably 490° C. or more, particularly preferably 495° C. or more. In the case where a gas barrier film, or the like is formed on the polyimide for the formation of a transistor on the polyimide, or the like, swelling may occur between the polyimide and the barrier film due to outgassing associated with the decomposition of the polyimide, and the like, when the polyimide has a low heat resistance. In general, it is preferred that the heat resistance is higher. In some applications, however, properties other than heat resistance are required, and the 5% weight loss temperature may be 470° C. or less.

A film of the polyimide obtained from the polyimide precursor of the present invention, that is, the polyimide of the present invention, or a laminate comprising at least one layer of the polyimide of the present invention may be suitably used as a film for TAB, a substrate for electric/electronic components, or a wiring board, and may be suitably used as a printed circuit board, a power circuit board, or a substrate for a flexible heater or a resistor, for example. The polyimide may also be useful in the applications of an insulating film and a protective film for electric/electronic components, and particularly an insulating film and a protective film which is formed on a material having a low coefficient of linear thermal expansion such as a base material for LSI, and the like.

Meanwhile, in the case where an alicyclic tetracarboxylic acid component is used as the tetracarboxylic acid component, in particular, the polyimide has excellent properties such as high transparency, bending resistance and high heat resistance, and has a very low coefficient of linear thermal expansion, and therefore the polyimide may be suitably used in the applications of transparent substrate for display, transparent substrate for touch panel, or substrate for solar battery.

One example of a method for producing a polyimide film/base laminate, or a polyimide film with the use of the polyimide precursor of the present invention will be described hereinafter. However, the method is not limited to the following method.

For example, a varnish of the polyimide precursor of the present invention is flow-cast on a base of ceramic (glass, silicon, or alumina), metal (copper, aluminum, or stainless steel), heat-resistant plastic film (polyimide), or the like, and dried at a temperature of 20° C. to 180° C., preferably 20° C. to 150° C., by the use of hot air or infrared ray in a vacuum, in an inert gas such as nitrogen, or in air. And then, the obtained polyimide precursor film is heated and imidized at a temperature of 200° C. to 500° C., more preferably about 250° C. to about 450° C., by the use of hot air or infrared ray in a vacuum, in an inert gas such as nitrogen, or in air, wherein the polyimide precursor film is on the base, or alternatively, the polyimide precursor film is peeled from the base and fixed at the edges, to provide a polyimide film/base laminate, or a polyimide film. The thermal imidization is preferably performed in a vacuum or in an inert gas so as to prevent oxidation and degradation of the obtained polyimide film. The thermal imidization may be performed in air if the thermal imidization temperature is not too high. At this point, the thickness of the polyimide film (the polyimide film layer, in the case of a polyimide film/base laminate) is preferably 1 μm to 250 μm, more preferably 1 μm to 150 μm, in view of the transportability in the subsequent steps.

A flexible conductive substrate may be obtained by forming a conductive layer on one surface or both surfaces of the polyimide film/base laminate or the polyimide film thus obtained.

A flexible conductive substrate may be obtained by the following methods, for example. As for the first method, the polyimide film is not peeled from the base in the “polyimide film/base” laminate, and a conductive layer of a conductive material (metal or metal oxide, conductive organic material, conductive carbon, or the like) is formed on the surface of the polyimide film by sputtering, vapor deposition, printing, or the like, to provide a “conductive layer/polyimide film/base” conductive laminate. And then, as necessary, the “electrically-conductive layer/polyimide film” laminate is peeled from the base, to provide a flexible conductive substrate which consists of the “conductive layer/polyimide film” laminate.

As for the second method, the polyimide film is peeled from the base in the “polyimide film/base” laminate to obtain the polyimide film, and then a conductive layer of a conductive material (metal or metal oxide, conductive organic material, conductive carbon, or the like) is formed on the surface of the polyimide film in the same way as in the first method, to provide a flexible conductive substrate which consists of the “conductive layer/polyimide film” laminate, or the “conductive layer/polyimide film/conductive layer” laminate.

In the first and the second methods, a gas barrier layer against water vapor, oxygen, or the like, and an inorganic layer such as a light-controlling layer may be formed on the surface of the polyimide film by sputtering, vapor deposition, gel-sol process, or the like, as necessary, before the conductive layer is formed.

In addition, a circuit may be suitably formed on the conductive layer by photolithography process, various printing processes, ink-jet process, or the like.

The substrate thus obtained comprises a circuit of a conductive layer on a surface of a polyimide film formed of the polyimide of the present invention, optionally with a gas barrier layer or an inorganic layer therebetween, as necessary. The substrate is flexible, and has excellent bending resistance, heat resistance, and mechanical properties, and also has a very low coefficient of linear thermal expansion up to a high temperature, and excellent solvent resistance, and therefore a fine circuit may be easily formed thereon.

A film of the polyimide of the present invention, or a laminate comprising at least one layer of the polyimide of the present invention may be suitably used as a film for TAB, a substrate for electric/electronic components, or a wiring board, and may be suitably used as a printed circuit board, a power circuit board, or a substrate for a flexible heater or a resistor, for example. The polyimide may also be useful in the applications of an insulating film and a protective film for electric/electronic components, and particularly an insulating film and a protective film which is formed on a material having a low coefficient of linear thermal expansion such as a base material for LSI, and the like.

Meanwhile, the polyimide of the present invention in which an alicyclic tetracarboxylic acid component (alicyclic tetracarboxylic dianhydride, or the like) is used as the tetracarboxylic acid component, in particular, has high transparency in addition to the properties as described above. Accordingly, a film of the polyimide, or a laminate comprising at least one layer of the polyimide may be suitably used as a substrate for a display, a substrate for a touch panel, a substrate for a solar battery, and the like.

More specifically, a flexible thin-film transistor is produced by further forming a transistor (inorganic transistor, or organic transistor) on the substrate by vapor deposition, various printing processes, ink-jet process, or the like, and is suitably used as a liquid crystal device for display device, an EL device, or a photoelectric device.

### EXAMPLES

The present invention will be further described hereinafter with reference to Examples and Comparative Examples. However, the present invention is not limited to the following Examples.

In each of the following Examples, the evaluations were conducted by the following methods.

### <Evaluation of Varnish of Polyimide Precursor>

[Logarithmic Viscosity]

The various polyimide precursor solutions at a concentration of 0.5 g/dL were prepared, and the logarithmic viscosity was determined by the measurement of the viscosity at 30° C. using an Ubbelohde viscometer.

[Imidization Degree]

The ¹H-NMR measurement of the polyimide precursor solution was carried out with M-AL400 made by JEOL Ltd. using dimethyl sulfoxide-d₆ as the solvent, and the imidization degree [the amount of the repeating unit represented by the chemical formula (2) relative to the total repeating units] was calculated from the ratio of the integral value of the peak of aromatic proton to the integral value of the peak of carboxylic proton by the following formula (I).

Imidization degree (%)={1−(Y/Z)×(1/X)}×100 (I)
X: integral value of the peak of carboxylic proton/integral value of the peak of aromatic proton in the case of 0% of imidization degree, determined from the amounts of the charged monomers
Y: integral value of the peak of carboxylic proton, obtained from ¹H-NMR measurement
Z: integral value of the peak of aromatic proton, obtained from ¹H-NMR measurement

Specific examples are described below.

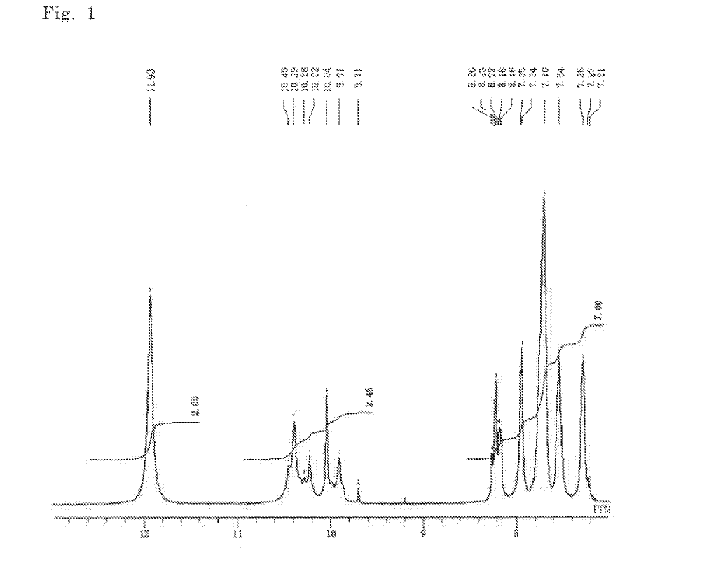

FIG. 1 shows the result of the ¹H-NMR measurement of the polyimide precursor solution of Comparative Example 3. The peak around chemical shift 7-8.3 ppm on the horizontal axis is the peak of aromatic proton, the peak around 9.6-10.6 ppm is the peak of amide proton, and the peak around 12 ppm is the peak of carboxylic proton. It is assumed that the polyimide precursor of Comparative Example 3 has an imidization degree of 0%, because the monomers were reacted under the reaction condition that the imidization does not proceed. The ratio of the integral value of the peak of aromatic proton to the integral value of the peak of carboxylic proton in the case of 0% of imidization degree, which is calculated from the amounts of the charged monomers, is 7:2. In the result of the ¹H-NMR measurement, the ratio of the integral value of the peak of aromatic proton to the integral value of the peak of carboxylic proton was 7:2, and it was confirmed that the imidization degree was 0%.

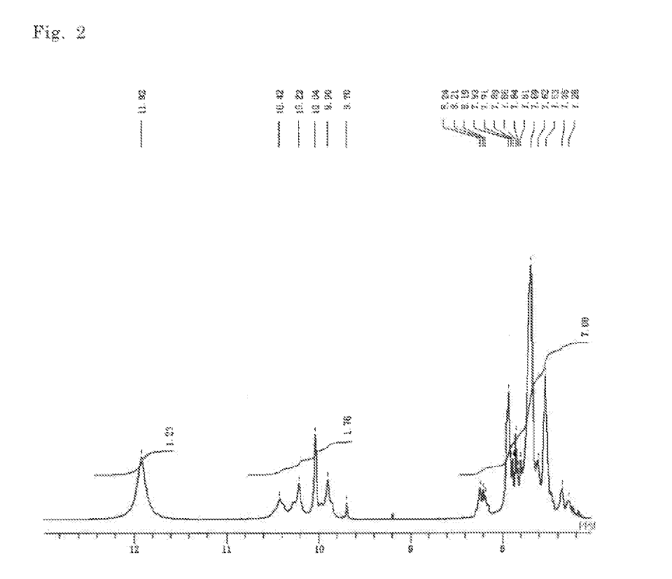

FIG. 2 shows the result of the ¹H-NMR measurement of the polyimide precursor solution of Example 19. The integral value of the peak of aromatic proton around chemical shift 7-8.3 ppm was 7, whereas the integral value of the peak of carboxylic proton around 12 ppm was 1.23. As shown above, in the case of 0% of imidization degree, the ratio of the integral value of the peak of aromatic proton to the integral value of the peak of carboxylic proton is 7:2. The reason why the ratio of the integral value of the peak of aromatic proton to the integral value of the peak of carboxylic proton was 7:1.23 in the result of the ¹H-NMR measurement of the polyimide precursor solution of Example 19 is that the imidization proceeded and the amount of carboxylic acid was decreased.

The imidization degree of Example 19 was calculated by the formula (I) to be 38.5%.

$$\begin{matrix}Imidization degree ( \% ) = [ 1 - ( 1.23 / 7 ) \times \{ 1 / ( 2 / 7 ) \} ] \times 100 \\ = 38.5\end{matrix}$$

### <Evaluation of Polyimide Film>

[Light Transmittance at 400 nm, Total Light Transmittance]

The light transmittance at 400 nm and the total light transmittance (average light transmittance at 380 nm to 780 nm) of the polyimide film having a thickness of about 10 μm were measured using MCPD-300 made by Otsuka Electronics Co., Ltd. The light transmittance at 400 nm and the total light transmittance of the film having a thickness of 10 μm were calculated from the measured light transmittance at 400 nm and the measured total light transmittance using the Lambert-Beer formula on the assumption that the reflectance was 10%. The calculating formulas are shown below.

Log₁₀((T₁+10)/100)=10/L×(Log₁₀((T₁′+10)/100))

Log₁₀((T₂+10)/100)=10/L×(Log₁₀((T₂′+10)/100))
T₁: light transmittance at 400 nm of the polyimide film having a thickness of 10 μm on the assumption that the reflectance is 10% (%)
T₁′: measured light transmittance at 400 nm (%)
T₂: total light transmittance of the polyimide film having a thickness of 10 μm on the assumption that the reflectance is 10% (%)
T₂′: measured total light transmittance (%)
L: thickness of the polyimide film measured (μm)

[Modulus of Elasticity, Elongation at Break, Breaking Strength]

The polyimide film having a thickness of about 10 μm was cut to the dumbbell shape of IEC450 standard, which was used as a test piece, and the initial modulus of elasticity, the elongation at break, and the breaking strength were measured at a distance between chucks of 30 mm and a tensile speed of 2 mm/min using TENSILON made by Orientec Co., Ltd.

[Coefficient of Linear Thermal Expansion (CTE)]

The polyimide film having a thickness of about 10 μm was cut to a rectangle having a width of 4 mm, which was used as a test piece, and the test piece was heated to 500° C. at a distance between chucks of 15 mm, a load of 2 g and a temperature-increasing rate of 20° C./min using TMA/SS6100 (made by SII Nanotechnology Inc). The coefficient of linear thermal expansion from 50° C. to 200° C. was determined from the obtained TMA curve.

[5% Weight Loss Temperature]

The polyimide film having a thickness of about 10 μm was used as a test piece, and the test piece was heated from 25° C. to 600° C. at a temperature-increasing rate of 10° C./min in a flow of nitrogen using a thermogravimetric analyzer (Q5000IR) made by TA Instruments Inc. The 5% weight loss temperature was determined from the obtained weight curve.

[Solubility Test]

The polyimide film having a thickness of about 10 μm was used as a test piece, and the test piece was immersed in N,N-dimethylacetamide for 5 minutes, and the one in which no change was visually observed was evaluated as “∘” and the one in which white-turbidity or dissolution was observed was evaluated as “x”.

The abbreviations, purities, etc. of the raw materials used in each of the following Examples are as follows.

[Diamine Component]

DABAN: 4,4′-diaminobenzanilide [purity: 99.90% (GC analysis)]
TFMB: 2,2′-bis(trifluoromethyl)benzidine [purity: 99.83% (GC analysis)]
PPD: p-phenylenediamine [purity: 99.9% (GC analysis)]
FDA: 9,9-bis(4-aminophenyl)fluorene
BAPB: 4,4′-bis(4-aminophenoxy)biphenyl

[Tetracarboxylic Acid Component]

CpODA: norbornane-2-spiro-α-cyclopentanone-α′-spiro-2″-norbornane-5,5″,6,6″-tetracarboxylic dianhydride
DNDAxx: (4arH,8acH)-decahydro-1t,4t:5c,8c-dimethanonaphthalene-2t,3t,6c,7c-tetracarboxylic dianhydride [purity as DNDAxx: 99.2% (GC analysis)]
s-BPDA: 3,3′,4,4′-biphenyltetracarboxylic dianhydride
ODPA: 4, 4′-oxydiphthalic dianhydride

[Solvent]

### DMAc: N,N-dimethylacetamide

NMP: 1-methyl-2-pyrrolidone

The structural formulas of the tetracarboxylic acid components and the diamine components used in Examples and Comparative Examples are shown in Table 1.

TABLE 1

| Tetracarboxylic dianhydride | Diamine |
|---|---|
| 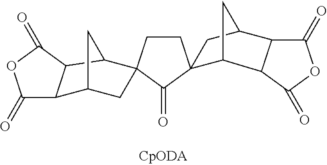 [SMILES: O=C1OC(=O)C2C1C1CC2C2(CCC3(CC4CC3C3C(=O)OC(=O)C43)C2=O)C1] | 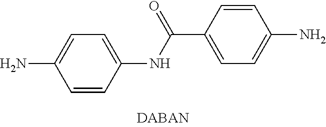 [SMILES: Nc1ccc(NC(=O)c2ccc(N)cc2)cc1] |
| 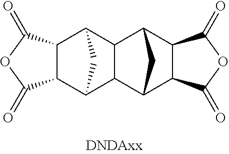 [SMILES: O=C1OC(=O)[C@H]2[C@@H]1[C@H]1C[C@@H]2C2C1[C@@H]1C[C@H]2[C@H]2C(=O)OC(=O)[C@H]21] | 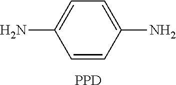 |
| 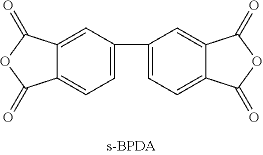 [SMILES: O=C1OC(=O)c2cc(-c3ccc4c(c3)C(=O)OC4=O)ccc21] | 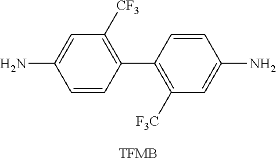 [SMILES: Nc1ccc(-c2ccc(N)cc2C(F)(F)F)c(C(F)(F)F)c1] |
| 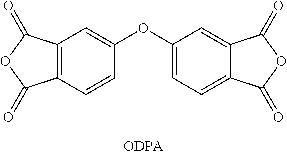 [SMILES: O=C1OC(=O)c2cc(Oc3ccc4c(c3)C(=O)OC4=O)ccc21] | 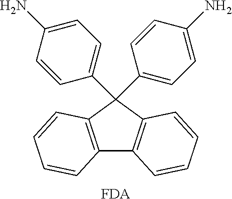 |
| | 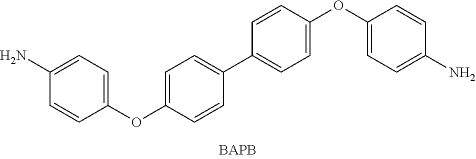 [SMILES: Nc1ccc(Oc2ccc(-c3ccc(Oc4ccc(N)cc4)cc3)cc2)cc1] |

### Example 1

2.000 g (6.246 mmol) of TFMB was placed in a reaction vessel, which was purged with nitrogen gas, and 32.8 g of DMAc was added thereto such that the total mass of the charged monomers (total mass of the diamine component and the carboxylic acid component) was 20 mass %, and then the mixture was stirred at room temperature for 1 hour. 1.600 g (4.164 mmol) of CpODA was gradually added to the resulting solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 2, and the both terminals are amino groups. 1.419 g (6.246 mmol) of DABAN was added to the solution, and the mixture was stirred at room temperature for 1 hour. 3.201 g (8.327 mmol) of CpODA was added to the resulting solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-1.

### Example 2

1.500 g (4.684 mmol) of TFMB was placed in a reaction vessel, which was purged with nitrogen gas, and 24.7 g of DMAc was added thereto such that the total mass of the charged monomers (total mass of the diamine component and the carboxylic acid component) was 20 mass %, and then the mixture was stirred at room temperature for 1 hour. 1.350 g (3.513 mmol) of CpODA was gradually added to the resulting solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 3, and the both terminals are amino groups. 1.065 g (4.684 mmol) of DABAN was added to the solution, and the mixture was stirred at room temperature for 1 hour. 2.251 g (5.855 mmol) of CpODA was added to the resulting solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-1.

### Example 3

1.500 g (4.684 mmol) of TFMB was placed in a reaction vessel, which was purged with nitrogen gas, and 24.7 g of DMAc was added thereto such that the total mass of the charged monomers (total mass of the diamine component and the carboxylic acid component) was 20 mass %, and then the mixture was stirred at room temperature for 1 hour. 1.575 g (4.099 mmol) of CpODA was gradually added to the resulting solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 7, and the both terminals are amino groups. 1.065 g (4.684 mmol) of DABAN was added to the solution, and the mixture was stirred at room temperature for 1 hour. 2.026 g (5.270 mmol) of CpODA was added to the resulting solution, and the mixture was stirred at room temperature for 24 hours, to provide a homogeneous and viscous polyimide precursor solution. The logarithmic viscosity of the obtained polyimide precursor was 0.7 dL/g.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-1.

### Example 4

1.500 g (4.684 mmol) of TFMB was placed in a reaction vessel, which was purged with nitrogen gas, and 24.7 g of DMAc was added thereto such that the total mass of the charged monomers (total mass of the diamine component and the carboxylic acid component) was 20 mass %, and then the mixture was stirred at room temperature for 1 hour. 1.688 g (4.391 mmol) of CpODA was gradually added to the resulting solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 15, and the both terminals are amino groups. 1.065 g (4.684 mmol) of DABAN was added to the solution, and the mixture was stirred at room temperature for 1 hour. 1.913 g (4.977 mmol) of CpODA was added to the resulting solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-1.

### Example 5

1.500 g (4.684 mmol) of TFMB was placed in a reaction vessel, which was purged with nitrogen gas, and 24.7 g of DMAc was added thereto such that the total mass of the charged monomers (total mass of the diamine component and the carboxylic acid component) was 20 mass %, and then the mixture was stirred at room temperature for 1 hour. 1.764 g (4.590 mmol) of CpODA was gradually added to the resulting solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 49, and the both terminals are amino groups. 1.065 g (4.684 mmol) of DABAN was added to the solution, and the mixture was stirred at room temperature for 1 hour. 1.836 g (4.778 mmol) of CpODA was added to the resulting solution, and the mixture was stirred at room temperature for 24 hours, to provide a homogeneous and viscous polyimide precursor solution. The logarithmic viscosity of the obtained polyimide precursor was 0.6 dL/g.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-1.

### Example 6

1.500 g (4.684 mmol) of TFMB was placed in a reaction vessel, which was purged with nitrogen gas, and 24.7 g of DMAc was added thereto such that the total mass of the charged monomers (total mass of the diamine component and the carboxylic acid component) was 20 mass %, and then the mixture was stirred at room temperature for 1 hour. 1.799 g (4.679 mmol) of CpODA was gradually added to the resulting solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 999, and the both terminals are amino groups. 1.065 g (4.684 mmol) of DABAN was added to the solution, and the mixture was stirred at room temperature for 1 hour. 1.802 g (4.689 mmol) of CpODA was added to the resulting solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-1.

### Example 7

3.601 g (9.368 mmol) of CpODA was placed in a reaction vessel, which was purged with nitrogen gas, and 24.7 g of DMAc was added thereto such that the total mass of the charged monomers (total mass of the diamine component and the carboxylic acid component) was 20 mass %, and then the mixture was stirred at 50° C. for 1 hour, to provide a homogeneous solution. 1.500 g (4.684 mmol) of TFMB was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 1, and the both terminals are acid anhydride groups. 1.065 g (4.684 mmol) of DABAN was added to the solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-1.

### Example 8

3.000 g (7.805 mmol) of CpODA was placed in a reaction vessel, which was purged with nitrogen gas, and 27.4 g of DMAc was added thereto such that the total mass of the charged monomers (total mass of the diamine component and the carboxylic acid component) was 20 mass %, and then the mixture was stirred at 50° C. for 1 hour, to provide a homogeneous solution. 1.666 g (5.203 mmol) of TFMB was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 2, and the both terminals are acid anhydride groups. 1.183 g (5.203 mmol) of DABAN was added to the solution, and the mixture was stirred at 50° C. for 5 hours. 1.00 g (2.602 mmol) of CpODA was added to the resulting solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-1.

### Example 9

2.500 g (6.504 mmol) of CpODA was placed in a reaction vessel, which was purged with nitrogen gas, and 30.0 g of DMAc was added thereto such that the total mass of the charged monomers (total mass of the diamine component and the carboxylic acid component) was 20 mass %, and then the mixture was stirred at 50° C. for 1 hour, to provide a homogeneous solution. 1.822 g (5.691 mmol) of TFMB was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 7, and the both terminals are acid anhydride groups. 1.293 g (5.691 mmol) of DABAN was added to the solution, and the mixture was stirred at 50° C. for 5 hours. 1.875 g (4.878 mmol) of CpODA was added to the resulting solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-2.

### Example 10

2.500 g (6.504 mmol) of CpODA was placed in a reaction vessel, which was purged with nitrogen gas, and 32.1 g of DMAc was added thereto such that the total mass of the charged monomers (total mass of the diamine component and the carboxylic acid component) was 20 mass %, and then the mixture was stirred at 50° C. for 1 hour, to provide a homogeneous solution. 1.953 g (6.097 mmol) of TFMB was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 15, and the both terminals are acid anhydride groups. 1.386 g (6.097 mmol) of DABAN was added to the solution, and the mixture was stirred at 50° C. for 5 hours. 2.188 g (5.691 mmol) of CpODA was added to the resulting solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-2.

### Example 11

2.500 g (6.504 mmol) of CpODA was placed in a reaction vessel, which was purged with nitrogen gas, and 33.6 g of DMAc was added thereto such that the total mass of the charged monomers (total mass of the diamine component and the carboxylic acid component) was 20 mass %, and then the mixture was stirred at 50° C. for 1 hour, to provide a homogeneous solution. 2.041 g (6.374 mmol) of TFMB was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 49, and the both terminals are acid anhydride groups. 1.449 g (6.374 mmol) of DABAN was added to the solution, and the mixture was stirred at 50° C. for 5 hours. 2.40 g (6.244 mmol) of CpODA was added to the resulting solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-2.

### Example 12

2.500 g (6.504 mmol) of CpODA was placed in a reaction vessel, which was purged with nitrogen gas, and 34.2 g of DMAc was added thereto such that the total mass of the charged monomers (total mass of the diamine component and the carboxylic acid component) was 20 mass %, and then the mixture was stirred at 50° C. for 1 hour, to provide a homogeneous solution. 2.081 g (6.497 mmol) of TFMB was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 999, and the both terminals are acid anhydride groups. 1.477 g (6.497 mmol) of DABAN was added to the solution, and the mixture was stirred at 50° C. for 5 hours. 2.495 g (6.491 mmol) of CpODA was added to the resulting solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-2.

### Example 13

3.555 g (11.101 mmol) of TFMB was placed in a reaction vessel, which was purged with nitrogen gas, and 36.1 g of NMP was added thereto, and then the mixture was stirred at room temperature for 1 hour, to provide a homogeneous solution. 2.844 g (7.399 mmol) of CpODA was gradually added to the solution, and the mixture was stirred at 50° C. for 5 hours. Subsequently, the mixture was heated to 170° C., and 25 mL of toluene was added thereto and toluene was refluxed for 5 hours, and then toluene was extracted and the resulting solution was cooled to room temperature. The solution was dropped into 500 mL of water, to precipitate a solid imide compound TFMB5 (The polymerization degree (n) of the imide compound, which is calculated from the amounts of the charged monomers, is 2, and the both terminals are amino groups.) and the imide compound was collected and dried under reduced pressure. 1.617 g (1.173 mmol) of the obtained TFMB5 and 0.800 g (3.520 mmol) of DABAN were placed, and 16.9 g of DMAc was added thereto such that the total mass of the charged monomers (total mass of the diamine component and the carboxylic acid component) was 20 mass %, and then the mixture was stirred at room temperature for 1 hour. 1.804 g (4.693 mmol) of CpODA was added to the resulting solution, and the mixture was stirred at room temperature for 24 hours, to provide a homogeneous and viscous polyimide precursor solution. The logarithmic viscosity of the obtained polyimide precursor was 0.8 dL/g.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-2.

### Example 14

0.713 g (3.136 mmol) of DABAN and 1.004 g (3.136 mmol) of TFMB were placed in a reaction vessel, which was purged with nitrogen gas, and 16.5 g of DMAc was added thereto such that the total mass of the charged monomers (total mass of the diamine component and the carboxylic acid component) was 20 mass %, and then the mixture was stirred at room temperature for 1 hour. 2.411 g (6.272 mmol) of CpODA was gradually added to the resulting solution, and the mixture was stirred at room temperature for 24 hours. Subsequently, the mixture was heated to 160° C., and 25 mL of toluene was added thereto and toluene was refluxed for 15 minutes, and then toluene was extracted and the resulting solution was cooled to room temperature, to provide a homogeneous and viscous polyimide precursor solution (imidization degree: 52%).

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-2.

### Example 15

0.713 g (3.136 mmol) N and 1.004 g (3.136 mmol) of TFMB were placed in a reaction vessel, which was purged with nitrogen gas, and 16.5 g of DMAc was added thereto such that the total mass of the charged monomers (total mass of the diamine component and the carboxylic acid component) was 20 mass %, and then the mixture was stirred at room temperature for 1 hour. 2.411 g (6.272 mmol) of CpODA was gradually added to the resulting solution, and the mixture was stirred at room temperature for 24 hours. Subsequently, the mixture was heated to 160° C., and 25 mL of toluene was added thereto and toluene was refluxed for 10 minutes, and then toluene was extracted and the resulting solution was cooled to room temperature, to provide a homogeneous and viscous polyimide precursor solution (imidization degree: 44%).

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-2.

### Comparative Example 1

0.713 g (3.136 mmol) of DABAN and 1.004 g (3.136 mmol) of TFMB were placed in a reaction vessel, which was purged with nitrogen gas, and 16.5 g of DMAc was added thereto such that the total mass of the charged monomers (total mass of the diamine component and the carboxylic acid component) was 20 mass %, and then the mixture was stirred at room temperature for 1 hour. 2.411 g (6.272 mmol) of CpODA was gradually added to the resulting solution, and the mixture was stirred at room temperature for 24 hours, to provide a homogeneous and viscous polyimide precursor solution (imidization degree: 0%). The logarithmic viscosity of the obtained polyimide precursor was 0.2 dL/g.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-2.

### Reference Example 1

0.713 g (3.136 mmol) of DABAN and 1.004 g (3.136 mmol) of TFMB were placed in a reaction vessel, which was purged with nitrogen gas, and 16.5 g of DMAc was added thereto such that the total mass of the charged monomers (total mass of the diamine component and the carboxylic acid component) was 20 mass %, and then the mixture was stirred at room temperature for 1 hour. 2.411 g (6.272 mmol) of CpODA was gradually added to the resulting solution, and the mixture was stirred at room temperature for 24 hours. Subsequently, the mixture was heated to 160° C., and 25 mL of toluene was added thereto and toluene was refluxed for 30 minutes, and then a precipitate was observed. And then, the resulting solution was cooled to room temperature, but the precipitate was further increased and a homogeneous varnish could not be obtained.

### Example 16

4.502 g (11.711 mmol) of CpODA was placed in a reaction vessel, which was purged with nitrogen gas, and 29.3 g of DMAc was added thereto such that the total mass of the charged monomers (total mass of the diamine component and the carboxylic acid component) was 20 mass %, and then the mixture was stirred at 50° C. for 1 hour, to provide a homogeneous solution. 1.500 g (4.684 mmol) of TFMB was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 1, and the both terminals are acid anhydride groups. 1.065 g (4.684 mmol) of DABAN and 0.253 g (2.342 mmol) of PPD were added to the solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-3.

### Example 17

4.502 g (11.711 mmol) of CpODA was placed in a reaction vessel, which was purged with nitrogen gas, and 29.3 g of DMAc was added thereto such that the total mass of the charged monomers (total mass of the diamine component and the carboxylic acid component) was 20 mass %, and then the mixture was stirred at 50° C. for 1 hour, to provide a homogeneous solution. 1.500 g (4.684 mmol) of TFMB and 0.253 g (2.342 mmol) of PPD were gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 1, and the both terminals are acid anhydride groups. 1.065 g (4.684 mmol) of DABAN was added to the solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-3.

### Comparative Example 2

0.355 g (1.561 mmol) of DABAN, 0.50 g (1.561 mmol) of TFMB and 0.084 g (0.781 mmol) of PPD were placed in a reaction vessel, which was purged with nitrogen gas, and 9.8 g of DMAc was added thereto such that the total mass of the charged monomers (total mass of the diamine component and the carboxylic acid component) was 20 mass %, and then the mixture was stirred at room temperature for 1 hour. 1.500 g (3.903 mmol) of CpODA was gradually added to the resulting solution, and the mixture was stirred at room temperature for 24 hours, to provide a homogeneous and viscous polyimide precursor solution (imidization degree: 0%).

The polyimide precursor solution, which was filtered through a PTFE membrane filter, was applied on a glass substrate, and then the polyimide precursor was thermally imidized by heating the polyimide precursor solution on the glass substrate from room temperature to 420° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-3.

### Example 18

1.500 g (4.684 mmol) of TFMB was placed in a reaction vessel, which was purged with nitrogen gas, and 21.6 g of DMAc was added thereto such that the total mass of the charged monomers (total mass of the diamine component and the carboxylic acid component) was 20 mass %, and then the mixture was stirred at room temperature for 1 hour. 1.239 g (4.099 mmol) of DNDAxx was gradually added to the resulting solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 7, and the both terminals are amino groups. 1.065 g (4.684 mmol) of DABAN was added to the solution, and the mixture was stirred at room temperature for 1 hour. 1.593 g (5.270 mmol) of DNDAxx was added to the resulting solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-3.

### Example 19

1.50 g (4.684 mmol) of TFMB was placed in a reaction vessel, which was purged with nitrogen gas, and 21.6 g of DMAc was added thereto such that the total mass of the charged monomers (total mass of the diamine component and the carboxylic acid component) was 20 mass %, and then the mixture was stirred at room temperature for 1 hour. 1.388 g (4.591 mmol) of DNDAxx was gradually added to the resulting solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 49, and the both terminals are amino groups. 1.065 g (4.684 mmol) of DABAN was added to the solution, and the mixture was stirred at room temperature for 1 hour. 1.444 g (4.778 mmol) of DNDAxx was added to the resulting solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-3.

### Example 201

3.776 g (12.491 mmol) of DNDAxx was placed in a reaction vessel, which was purged with nitrogen gas, and 28.8 g of DMAc was added thereto such that the total mass of the charged monomers (total mass of the diamine component and the carboxylic acid component) was 20 mass %, and then the mixture was stirred at 50° C. for 1 hour, to provide a homogeneous solution. 2.000 g (6.246 mmol) of TFMB and 0.568 g (2.498 mmol) of DABAN were gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 1, and the both terminals are acid anhydride groups. 0.852 g (3.747 mmol) of DABAN was added to the solution, and the mixture was stirred at room temperature for 24 hours, to provide a homogeneous and viscous polyimide precursor solution. The logarithmic viscosity of the obtained polyimide precursor was 0.8 dL/g.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-3.

### Comparative Example 3

0.800 g (3.520 mmol) of DABAN and 1.127 g (3.520 mmol) of TFMB were placed in a reaction vessel, which was purged with nitrogen gas, and 16.6 g of DMAc was added thereto such that the total mass of the charged monomers (total mass of the diamine component and the carboxylic acid component) was 20 mass %, and then the mixture was stirred at room temperature for 1 hour. 2.128 g (7.040 mmol) of DNDAxx was gradually added to the resulting solution, and the mixture was stirred at room temperature for 24 hours, to provide a homogeneous and viscous polyimide precursor solution (imidization degree: 0%). The logarithmic viscosity of the obtained polyimide precursor was 0.6 dL/g.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-3.

### Example 21

1.773 g (5.867 mmol) of DNDAxx was placed in a reaction vessel, which was purged with nitrogen gas, and 15.6 g of DMAc was added thereto such that the total mass of the charged monomers (total mass of the diamine component and the carboxylic acid component) was 15 mass %, and then the mixture was stirred at 50° C. for 1 hour, to provide a homogeneous solution. 0.400 g (1.760 mmol) of DABAN was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 1, and the both terminals are acid anhydride groups. 0.267 g (1.173 mmol) of DABAN and 0.317 g (2.933 mmol) of PPD were added to the solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-4.

### Example 22

2.130 g (7.048 mmol) of DNDAxx was placed in a reaction vessel, which was purged with nitrogen gas, and 29.8 g of DMAc was added thereto such that the total mass of the charged monomers (total mass of the diamine component and the carboxylic acid component) was 10 mass %, and then the mixture was stirred at 50° C. for 1 hour, to provide a homogeneous solution. 0.801 g (3.524 mmol) of DABAN was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 1, and the both terminals are acid anhydride groups. 0.381 g (3.524 mmol) of PPD was added to the solution, and the mixture was stirred at room temperature for 24 hours. The resulting solution was concentrated under reduced pressure, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-4.

### Example 23

1.400 g (6.160 mmol) of DABAN and 0.666 g (6.160 mmol) of PPD were placed in a reaction vessel, which was purged with nitrogen gas, and 23.5 g of DMAc was added thereto such that the total mass of the charged monomers (total mass of the diamine component and the carboxylic acid component) was 20 mass %, and then the mixture was stirred at room temperature for 1 hour. 3.724 g (12.320 mmol) of DNDAxx was gradually added to the resulting solution, and the mixture was stirred at room temperature for 24 hours. Subsequently, the mixture was heated to 160° C., and 25 mL of toluene was added thereto and toluene was refluxed for 15 minutes, and then toluene was extracted and the resulting solution was cooled to room temperature, to provide a homogeneous and viscous polyimide precursor solution (imidization degree: 50%).

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-4.

### Example 24

1.400 g (6.160 mmol) of DABAN and 0.666 g (6.160 mmol) of PPD were placed in a reaction vessel, which was purged with nitrogen gas, and 23.5 g of DMAc was added thereto such that the total mass of the charged monomers (total mass of the diamine component and the carboxylic acid component) was 20 mass %, and then the mixture was stirred at room temperature for 1 hour. 3.724 g (12.320 mmol) of DNDAxx was gradually added to the resulting solution, and the mixture was stirred at room temperature for 24 hours. Subsequently, the mixture was heated to 160° C., and 25 mL of toluene was added thereto and toluene was refluxed for 20 minutes, and then toluene was extracted and the resulting solution was cooled to room temperature, to provide a homogeneous and viscous polyimide precursor solution (imidization degree: 69%).

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-4.

### Comparative Example 4

0.800 g (3.520 mmol) of DABAN and 0.381 g (3.520 mmol) of PPD were placed in a reaction vessel, which was purged with nitrogen gas, and 13.4 g of DMAc was added thereto such that the total mass of the charged monomers (total mass of the diamine component and the carboxylic acid component) was 20 mass %, and then the mixture was stirred at room temperature for 1 hour. 2.128 g (7.040 mmol) of DNDAxx was gradually added to the resulting solution, and the mixture was stirred at room temperature for 24 hours, to provide a homogeneous and viscous polyimide precursor solution (imidization degree: 0%). The logarithmic viscosity of the obtained polyimide precursor was 0.7 dL/g.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-4.

### Comparative Example 5

0.798 g (2.640 mmol) of DNDAxx was placed in a reaction vessel, which was purged with nitrogen gas, and 23.6 g of DMAc was added thereto such that the total mass of the charged monomers (total mass of the diamine component and the carboxylic acid component) was 5 mass %, and then the mixture was stirred at 50° C. for 1 hour, to provide a homogeneous solution. 0.029 g (0.264 mmol) of PPD was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 1, and the both terminals are acid anhydride groups. 0.300 g (1.320 mmol) of DABAN and 0.114 g (1.056 mmol) of PPD were added to the solution, and the mixture was stirred at room temperature for 24 hours. The resulting solution was concentrated under reduced pressure, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-4.

### Comparative Example 6

2.660 g (8.800 mmol) of DNDAxx was placed in a reaction vessel, which was purged with nitrogen gas, and 23.4 g of DMAc was added thereto such that the total mass of the charged monomers (total mass of the diamine component and the carboxylic acid component) was 15 mass %, and then the mixture was stirred at 50° C. for 1 hour, to provide a homogeneous solution. 0.200 g (0.880 mmol) of DA RAN was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 1, and the both terminals are acid anhydride groups. 0.800 g (3.520 mmol) of DABAN and 0.476 g (4.400 mmol) of PPD were added to the solution, and the mixture was stirred at room temperature for 24 hours, to provide a homogeneous and viscous polyimide precursor solution. The logarithmic viscosity of the obtained polyimide precursor was 0.5 dL/g.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-4.

### Example 25

1.400 g (6.160 mmol) of DABAN and 0.666 g (6.160 mmol) of PPD were placed in a reaction vessel, which was purged with nitrogen gas, and 23.5 g of NMP was added thereto such that the total mass of the charged monomers (total mass of the diamine component and the carboxylic acid component) was 20 mass %, and then the mixture was stirred at room temperature for 1 hour. 3.724 g (12.320 mmol) of DNDAxx was gradually added to the resulting solution, and the mixture was stirred at room temperature for 24 hours. Subsequently, the mixture was heated to 160° C., and 25 mL of toluene was added thereto and toluene was refluxed for 20 minutes, and then toluene was extracted and the resulting solution was cooled to room temperature, to provide a homogeneous and viscous polyimide precursor solution (imidization degree: 73%).

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-4.

### Comparative Example 7

1.400 g (6.160 mmol) of DABAN and 0.666 g (6.160 mmol) of PPD were placed in a reaction vessel, which was purged with nitrogen gas, and 23.5 g of NMP was added thereto such that the total mass of the charged monomers (total mass of the diamine component and the carboxylic acid component) was 20 mass %, and then the mixture was stirred at room temperature for 1 hour. 3.724 g (12.320 mmol) of DNDAxx was gradually added to the resulting solution, and the mixture was stirred at room temperature for 24 hours, to provide a homogeneous and viscous polyimide precursor solution (imidization degree: 0%).

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-4.

### Example 26

3.540 g (11.711 mmol) of DNDAxx was placed in a reaction vessel, which was purged with nitrogen gas, and 25.4 g of DMAc was added thereto such that the total mass of the charged monomers (total mass of the diamine component and the carboxylic acid component) was 20 mass %, and then the mixture was stirred at 50° C. for 1 hour, to provide a homogeneous solution. 1.500 g (4.684 mmol) of TFMB was gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 1, and the both terminals are acid anhydride groups. 1.065 g (4.684 mmol) of DABAN and 0.253 g (2.342 mmol) of PPD were added to the solution, and the mixture was stirred at room temperature for 24 hours, to provide a homogeneous and viscous polyimide precursor solution.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-5.

### Example 27

5.542 g (18.334 mmol) of DNDAxx was placed in a reaction vessel, which was purged with nitrogen gas, and 36.7 g of DMAc was added thereto such that the total mass of the charged monomers (total mass of the diamine component and the carboxylic acid component) was 20 mass %, and then the mixture was stirred at 50° C. for 1 hour, to provide a homogeneous solution. 1.174 g (3.667 mmol) of TFMB and 0.500 g (2.200 mmol) of DABAN were gradually added to the solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 1, and the both terminals are acid anhydride groups. 1.167 g (5.133 mmol) of DABAN and 0.793 g (7.333 mmol) of PPD were added to the solution, and the mixture was stirred at room temperature for 24 hours, to provide a homogeneous and viscous polyimide precursor solution. The logarithmic viscosity of the obtained polyimide precursor was 0.6 dL/g.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-5.

### Example 28

1.409 g (4.400 mmol) of TFMB and 1.000 g (4.400 mmol) of DABAN were placed in a reaction vessel, which was purged with nitrogen gas, and 40.0 g of DMAc was added thereto such that the total mass of the charged monomers (total mass of the diamine component and the carboxylic acid component) was 20 mass %, and then the mixture was stirred at room temperature for 1 hour. 2.657 g (8.791 mmol) of DNDAxx was gradually added to the resulting solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to room temperature, to provide a solution containing an imide compound. The polymerization degree (n) of the imide compound, which is calculated from the amounts of the charged monomers, is 999, and the both terminals are amino groups. 1.000 g (4.400 mmol) of DABAN and 0.952 g (8.800 mmol) of PPD were added to the solution, and the mixture was stirred at room temperature for 5 hours. 3.993 g (13.209 mmol) of DNDAxx was added thereto, and the mixture was stirred at room temperature for 24 hours, to provide a homogeneous and viscous polyimide precursor solution. The logarithmic viscosity of the obtained polyimide precursor was 0.7 dL/g.

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-5.

### Example 29

3.325 g (11.000 mmol) of DNDAxx was placed in a reaction vessel, which was purged with nitrogen gas, and 21.3 g of DMAc was added thereto such that the total mass of the charged monomers (total mass of the diamine component and the carboxylic acid component) was 20 mass %, and then the mixture was stirred at room temperature for 1 hour. 0.383 g (1.100 mmol) of FDA was gradually added to the resulting solution, and the mixture was stirred at 50° C. for 5 hours. Subsequently, the mixture was heated to 160° C., and 25 mL of toluene was added thereto and toluene was refluxed for 3 hours, and then toluene was extracted and the resulting solution was cooled to 50° C. 1.000 g (4.400 mmol) of DABAN and 0.595 g (5.500 mmol) of PPD were added to the solution, and the mixture was stirred at 50° C. for 10 hours. Subsequently, the mixture was heated to 160° C., and 25 nit, of toluene was added thereto and toluene was refluxed for 15 minutes, and then toluene was extracted and the resulting solution was cooled to room temperature, to provide a homogeneous and viscous polyimide precursor solution. The logarithmic viscosity of the obtained polyimide precursor was 0.7 dL/g.

The polyimide precursor solution, which was filtered through a PTFE membrane filter, was applied on a glass substrate, and then the polyimide precursor was thermally imidized by heating the polyimide precursor solution on the glass substrate from room temperature to 450° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-5.

### Example 30

3.032 g (9.468 mmol) of TFMB was placed in a reaction vessel, which was purged with nitrogen gas, and 32.27 g of NMP was added thereto such that the total mass of the charged monomers (total mass of the diamine component and the carboxylic acid component) was 15 mass %, and then the mixture was stirred at room temperature for 1 hour. 2.786 g (9.468 mmol) of s-BPDA was gradually added to the resulting solution, and the mixture was stirred at room temperature for 24 hours. Subsequently, the mixture was heated to 160° C., and 25 mL of toluene was added thereto and toluene was refluxed for 15 minutes, and then toluene was extracted and the resulting solution was cooled to room temperature, to provide a homogeneous and viscous polyimide precursor solution (imidization degree: 50%).

The polyimide precursor solution, which was filtered through a PTFE membrane filter, was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-5.

### Comparative Example 8

3.032 g (9.468 mmol) of TFMB was placed in a reaction vessel, which was purged with nitrogen gas, and 32.27 g of NMP was added thereto such that the total mass of the charged monomers (total mass of the diamine component and the carboxylic acid component) was 15 mass %, and then the mixture was stirred at room temperature for 1 hour. 2.786 g (9.468 mmol) of s-BPDA was gradually added to the resulting solution, and the mixture was stirred at room temperature for 24 hours, to provide a homogeneous and viscous polyimide precursor solution (imidization degree: 0%).

The polyimide precursor solution, which was filtered through a PTFE membrane filter, was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-5.

### Example 31

2.000 g (6.246 mmol) of TFMB and 1.419 g (6.246 mmol) of DABAN were placed in a reaction vessel, which was purged with nitrogen gas, and 29.18 g of NMP was added thereto such that the total mass of the charged monomers (total mass of the diamine component and the carboxylic acid component) was 20 mass %, and then the mixture was stirred at room temperature for 1 hour. 3.875 g (12.491 mmol) of ODPA was gradually added to the resulting solution, and the mixture was stirred at room temperature for 24 hours. Subsequently, the mixture was heated to 160° C., and 25 mL of toluene was added thereto and toluene was refluxed for 15 minutes, and then toluene was extracted and the resulting solution was cooled to room temperature, to provide a homogeneous and viscous polyimide precursor solution (imidization degree: 47%).

The polyimide precursor solution, which was filtered through a PTFE membrane filter, was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-5.

### Comparative Example 9

2.000 g (6.246 mmol) of TFMB and 1.419 g (6.246 mmol) of DABAN were placed in a reaction vessel, which was purged with nitrogen gas, and 29.18 g of NMP was added thereto such that the total mass of the charged monomers (total mass of the diamine component and the carboxylic acid component) was 20 mass %, and then the mixture was stirred at room temperature for 1 hour. 3.875 g (12.491 mmol) of ODPA was gradually added to the resulting solution, and the mixture was stirred at room temperature for 24 hours, to provide a homogeneous and viscous polyimide precursor solution (imidization degree: 0%).

The polyimide precursor solution, which was filtered through a PTFE membrane filter, was applied on a glass substrate, and then the polyimide precursor was thermally imidized by heating the polyimide precursor solution on the glass substrate from room temperature to 410° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-5.

### Example 32

1.818 g (8.000 mmol) of DABAN, 1.108 g (1.000 mmol) of PPD and 0.368 g (1.000 mmol) of BAPB were placed in a reaction vessel, which was purged with nitrogen gas, and 21.27 g of NMP was added thereto such that the total mass of the charged monomers (total mass of the diamine component and the carboxylic acid component) was 20 mass %, and then the mixture was stirred at room temperature for 1 hour. 3.023 g (10.000 mmol) of DNDAxx was gradually added to the resulting solution, and the mixture was stirred at room temperature for 24 hours. Subsequently, the mixture was heated to 160° C., and 25 mL of toluene was added thereto and toluene was refluxed for 15 minutes, and then toluene was extracted and the resulting solution was cooled to room temperature, to provide a homogeneous and viscous polyimide precursor solution (imidization degree: 43%).

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-6.

### Comparative Example 10

1.818 g (8.000 mmol) of DABAN, 1.108 g (1.000 mmol) of PPD and 0.368 g (1.000 mmol) of BAPB were placed in a reaction vessel, which was purged with nitrogen gas, and 21.27 g of NMP was added thereto such that the total mass of the charged monomers (total mass of the diamine component and the carboxylic acid component) was 20 mass %, and then the mixture was stirred at room temperature for 1 hour. 3.023 g (10.000 mmol) of DNDAxx was gradually added to the resulting solution, and the mixture was stirred at room temperature for 24 hours, to provide a homogeneous and viscous polyimide precursor solution (imidization degree: 0%).

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-6.

### Example 33

1.591 g (7.000 mmol) of DABAN, 1.108 g (1.000 mmol) of PPD and 0.737 g (2.000 mmol) of BAPB were placed in a reaction vessel, which was purged with nitrogen gas, and 21.83 g of NMP was added thereto such that the total mass of the charged monomers (total mass of the diamine component and the carboxylic acid component) was 20 mass %, and then the mixture was stirred at room temperature for 1 hour. 3.023 g (10.000 mmol) of DNDAxx was gradually added to the resulting solution, and the mixture was stirred at room temperature for 24 hours. Subsequently, the mixture was heated to 160° C., and 25 mL of toluene was added thereto and toluene was refluxed for 15 minutes, and then toluene was extracted and the resulting solution was cooled to room temperature, to provide a homogeneous and viscous polyimide precursor solution (imidization degree: 35%).

The polyimide precursor solution, which was filtered through a PTFE membrane filter, was applied on a glass substrate, and then the polyimide precursor was thermally imidized by heating the polyimide precursor solution on the glass substrate from room temperature to 430° C. in a nitrogen atmosphere (oxygen concentration: 200 ppm or less), to provide a colorless and transparent polyimide film/glass laminate. Subsequently, the obtained polyimide film/glass laminate was immersed in water, and then the polyimide film was peeled from the glass and dried, to provide a polyimide film having a thickness of about 10 μm.

The results of the measurements of the properties of the polyimide film are shown in Table 2-6.

TABLE 2-1

| | | Example 1 | Example 2 | Example 3 | Example 4 |
|---|---|---|---|---|---|
| Polyimide precursor | | | | | |
| Tetracarboxylic | CpODA | 12.491 (4.164) | 9.368 (3.513) | 9.369 (4.099) | 9.368 (4.391) |
| acid component | DNDAxx | | | | |
| (imide compound | s-BPDA | | | | |
| synthesis) | ODPA | | | | |
| (mmol) | | | | | |
| Diamine | DABAN | 6.246 | 4.684 | 4.684 | 4.684 |
| component | TFMB | 6.246 (6.246) | 4.684 (4.684) | 4.684 (4.684) | 4.684 (4.684) |
| (imide compound | PPD | | | | |
| synthesis) | FDA | | | | |
| (mmol) | BAPB | | | | |
| | Imide compound | | | | |
| | TFMB5 | | | | |
| | (TFMB:CpODA = | | | | |
| | 3:2) | | | | |
| Imidization degree (%)* | | 33 | 38 | 44 | 45 |
| Polyimide film | | | | | |
| Light transmittance at 400 nm (%) | | 85 | 84 | 84 | 84 |
| Total light transmittance (%) | | 89 | 89 | 89 | 89 |
| Modulus of elasticity (GPa) | | 3.8 | 4.3 | 4 | 4.5 |
| Elongation at break (%) | | 30 | 27 | 27 | 26 |
| Breaking strength (MPa) | | 144 | 167 | 189 | 170 |
| Coefficient of linear thermal expansion | | 38 | 26 | 23 | 24 |
| (ppm/K) (50-200° C.) | | | | | |
| 5% weight loss temperature (° C.) | | 491 | 492 | 493 | 490 |
| Solubility test | | ◯ | ◯ | ◯ | ◯ |
| | | Example 5 | Example 6 | Example 7 | Example 8 |
| Polyimide precursor | | | | | |
| Tetracarboxylic | CpODA | 9.368 (4.590) | 9.368 (4.679) | 9.368 (9.368) | 10.407 (7.805) |
| acid component | DNDAxx | | | | |
| (imide compound | s-BPDA | | | | |
| synthesis) | ODPA | | | | |
| (mmol) | | | | | |
| Diamine | DABAN | 4.684 | 4.684 | 4.684 | 5.203 |
| component | TFMB | 4.684 (4.684) | 4.684 (4.684) | 4.684 (4.684) | 5.203 (5.203) |
| (imide compound | PPD | | | | |
| synthesis) | FDA | | | | |
| (mmol) | BAPB | | | | |
| | Imide compound | | | | |
| | TFMB5 | | | | |
| | (TFMB:CpODA = | | | | |
| | 3:2) | | | | |

| | | | | |
|---|---|---|---|---|
| Imidization degree (%)* | 39 | 38 | 50 | 50 |
| Polyimide film | | | | |
| Light transmittance at 400 nm (%) | 85 | 83 | 83 | 84 |
| Total light transmittance (%) | 89 | 89 | 88 | 89 |
| Modulus of elasticity (GPa) | 4.2 | 4.4 | 4.5 | 4.1 |
| Elongation at break (%) | 18 | 28 | 25 | 32 |
| Breaking strength (MPa) | 158 | 178 | 164 | 176 |
| Coefficient of linear thermal expansion | 23 | 22 | 21 | 26 |
| (ppm/K) (50-200° C.) | | | | |
| 5% weight loss temperature (° C.) | 494 | 490 | 488 | 491 |
| Solubility test | ◯ | ◯ | ◯ | ◯ |

*Imidization degree: the amount of the repeating unit represented by the chemical formula (2) relative to the total repeating units

TABLE 2-2

| | | Example 9 | Example 10 | Example 11 | Example 12 |
|---|---|---|---|---|---|
| Polyimide precursor | | | | | |
| Tetracarboxylic | CpODA | 11.382 (6.504) | 12.195 (6.504) | 12.748 (6.504) | 12.995 (6.504) |
| acid component | DNDAxx | | | | |
| (imide compound | s-BPDA | | | | |
| synthesis) | ODPA | | | | |
| (mmol) | | | | | |
| Diamine | DABAN | 5.691 | 6.097 | 6.374 | 6.497 |
| component | TFMB | 5.691 (5.691) | 6.097 (6.097) | 6.374 (6.374) | 6.497 (6.497) |
| (imide compound | PPD | | | | |
| synthesis) | FDA | | | | |
| (mmol) | BAPB | | | | |
| | Imide compound | | | | |
| | TFMB5 | | | | |
| | (TFMB:CpODA = | | | | |
| | 3:2) | | | | |

| | | | | |
|---|---|---|---|---|
| Imidization degree (%)* | 48 | 45 | 40 | 40 |
| Polyimide film | | | | |
| Light transmittance at 400 nm (%) | 85 | 84 | 84 | 85 |
| Total light transmittance (%) | 89 | 89 | 89 | 89 |
| Modulus of elasticity (GPa) | 4.2 | 4.1 | 4.1 | 4.2 |
| Elongation at break (%) | 28 | 38 | 23 | 28 |
| Breaking strength (MPa) | 164 | 199 | 173 | 172 |
| Coefficient of linear thermal expansion | 23 | 23 | 21 | 22 |
| (ppm/K) (50-200° C.) | | | | |
| 5% weight loss temperature (° C.) | 492 | 491 | 492 | 494 |
| Solubility test | ◯ | ◯ | ◯ | ◯ |

| | | | | | Comparative |
|---|---|---|---|---|---|
| | | Example 13 | Example 14 | Example 15 | Example 1 |
| Polyimide precursor | | | | | |
| Tetracarboxylic | CpODA | 4.693 | 6.272 | 6.272 | 6.272 |
| acid component | DNDAxx | | | | |
| (imide compound | s-BPDA | | | | |
| synthesis) | ODPA | | | | |
| (mmol) | | | | | |
| Diamine | DABAN | 3.520 | 3.136 | 3.136 | 3.136 |
| component | TFMB | | 3.136 | 3.136 | 3.136 |
| (imide compound | PPD | | | | |
| synthesis) | FDA | | | | |
| (mmol) | BAPB | | | | |
| | Imide compound | 1.173 | | | |
| | TFMB5 | | | | |
| | (TFMB:CpODA = | | | | |
| | 3:2) | | | | |

| | | | | |
|---|---|---|---|---|
| Imidization degree (%)* | 33 | 52 | 44 | 0 |
| Polyimide film | | | | |
| Light transmittance at 400 nm (%) | 80 | 84 | 84 | 83 |
| Total light transmittance (%) | 86 | 89 | 89 | 89 |
| Modulus of elasticity (GPa) | 4.4 | — | — | 3.4 |
| Elongation at break (%) | 9 | — | — | 35 |
| Breaking strength (MPa) | 136 | — | — | 145 |
| Coefficient of linear thermal expansion | 20 | 34 | 36 | 40 |
| (ppm/K) (50-200° C.) | | | | |
| 5% weight loss temperature (° C.) | 490 | 499 | 499 | 483 |
| Solubility test | ◯ | ◯ | ◯ | ◯ |

* Imidization degree: the amount of the repeating unit represented by the chemical formula (2) relative to the total repeating units

TABLE 2-3

| | | | | Comparative | |
|---|---|---|---|---|---|
| | | Example 16 | Example 17 | Example 2 | Example 18 |
| Polyimide precursor | | | | | |
| Tetracarboxylic | CpODA | 11.711 (11.711) | 11.711 (11.711) | 3.903 | |
| acid component | DNDAxx | | | | 9.369 (4.099) |
| (imide compound | s-BPDA | | | | |
| synthesis) | ODPA | | | | |
| (mmol) | | | | | |
| Diamine | DABAN | 4.684 | 4.684 | 1.561 | 4.684 |
| component | TFMB | 4.684 (4.684) | 4.684 (4.684) | 1.561 | 4.684 (4.684) |
| (imide compound | PPD | 2.342 | 2.342 (2.342) | 0.781 | |
| synthesis) | FDA | | | | |
| (mmol) | BAPB | | | | |
| | Imide compound | | | | |
| | TFMB5 | | | | |
| | (TFMB:CpODA = | | | | |
| | 3:2) | | | | |

| | | | | |
|---|---|---|---|---|
| Imidization degree (%)* | 40 | 60 | 0 | 44 |
| Polyimide film | | | | |
| Light transmittance at 400 nm (%) | 84 | 73 | 85 | 82 |
| Total light transmittance (%) | 87 | 83 | 89 | 89 |
| Modulus of elasticity (GPa) | 3.9 | 3.7 | 3.3 | 3.6 |
| Elongation at break (%) | 31 | 36 | 28 | 13 |
| Breaking strength (MPa) | 165 | 141 | 113 | 112 |
| Coefficient of linear thermal expansion | 22 | 27 | 44 | 37 |
| (ppm/K) (50-200° C.) | | | | |
| 5% weight loss temperature (° C.) | 494 | 496 | 492 | 505 |
| Solubility test | ◯ | ◯ | ◯ | ◯ |

| | | | | Comparative |
|---|---|---|---|---|
| | | Example 19 | Example 20 | Example 3 |
| Polyimide precursor | | | | |
| Tetracarboxylic | CpODA | | | |
| acid component | DNDAxx | 9.369 (4.591) | 12.491 (12.491) | 7.040 |
| (imide compound | s-BPDA | | | |
| synthesis) | ODPA | | | |
| (mmol) | | | | |
| Diamine | DABAN | 4.684 | 6.245 (2.498) | 3.520 |
| component | TFMB | 4.684 (4.684) | 6.246 (6.246) | 3.520 |
| (imide compound | PPD | | | |
| synthesis) | FDA | | | |
| (mmol) | BAPB | | | |
| | Imide compound | | | |
| | TFMB5 | | | |
| | (TFMB:CpODA = | | | |
| | 3:2) | | | |

| | | | |
|---|---|---|---|
| Imidization degree (%)* | 39 | 70 | 0 |
| Polyimide film | | | |
| Light transmittance at 400 nm (%) | 82 | 84 | 85 |
| Total light transmittance (%) | 89 | 89 | 90 |
| Modulus of elasticity (GPa) | 3.6 | 3.5 | 3.7 |
| Elongation at break (%) | 10 | 8 | 8 |
| Breaking strength (MPa) | 112 | 126 | 115 |
| Coefficient of linear thermal expansion | 39 | 22 | 43 |
| (ppm/K) (50-200° C.) | | | |
| 5% weight loss temperature (° C.) | 506 | 508 | 503 |
| Solubility test | ◯ | ◯ | ◯ |

*Imidization degree: the amount of the repeating unit represented by the chemical formula (2) relative to the total repeating units

TABLE 2-4

| | | | | | | Comparative |
|---|---|---|---|---|---|---|
| | | Example 21 | Example 22 | Example 23 | Example 24 | Example 4 |
| Polyimide precursor | | | | | | |
| Tetracarboxylic | CpODA | | | | | |
| acid component | DNDAxx | 5.867 (5.867) | 7.048 (7.048) | 12.320 | 12.320 | 7.040 |
| (imide compound | s-BPDA | | | | | |
| synthesis) | ODPA | | | | | |
| (mmol) | | | | | | |
| Diamine | DABAN | 2.933 (1.760) | 3.524 (3.524) | 6.160 | 6.160 | 3.520 |
| component | TFMB | | | | | |
| (imide compound | PPD | 2.933 | 3.524 | 6.160 | 6.160 | 3.520 |
| synthesis) | FDA | | | | | |
| (mmol) | BAPB | | | | | |
| | Imide compound | | | | | |
| | TFMB5 | | | | | |
| | (TFMB:CpODA = | | | | | |
| | 3:2) | | | | | |

| | | | | | |
|---|---|---|---|---|---|
| Imidization degree (%)* | 30 | 50 | 50 | 69 | 0 |
| Polyimide film | | | | | |
| Light transmittance at 400 nm (%) | 75 | 75 | 76 | 76 | 81 |
| Total light transmittance (%) | 84 | 85 | 86 | 86 | 88 |
| Modulus of elasticity (GPa) | 3.8 | 3.9 | 5.5 | 3.7 | 3.5 |
| Elongation at break (%) | 3 | 8 | 8 | 2 | 4 |
| Breaking strength (MPa) | 74 | 121 | 125 | 59 | 87 |
| Coefficient of linear thermal expansion | 29 | 28 | 25 | 24 | 41 |
| (ppm/K) (50-200° C.) | | | | | |
| 5% weight loss temperature (° C.) | 520 | 521 | 521 | 522 | 518 |
| Solubility test | ◯ | ◯ | ◯ | ◯ | ◯ |

| | | Comparative | Comparative | | Comparative |
|---|---|---|---|---|---|
| | | Example 5 | Example 6 | Example 25 | Example 7 |
| Polyimide precursor | | | | | |
| Tetracarboxylic | CpODA | | | | |
| acid component | DNDAxx | 2.640 (2.640) | 8.800 (8.800) | 12.320 | 12.320 |
| (imide compound | s-BPDA | | | | |
| synthesis) | ODPA | | | | |
| (mmol) | | | | | |
| Diamine | DABAN | 1.320 | 4.400 (0.880) | 6.160 | 6.160 |
| component | TFMB | | | | |
| (imide compound | PPD | 1.320 (0.264) | 4.400 | 6.160 | 6.160 |
| synthesis) | FDA | | | | |
| (mmol) | BAPB | | | | |
| | Imide compound | | | | |
| | TFMB5 | | | | |
| | (TFMB:CpODA = | | | | |
| | 3:2) | | | | |

| | | | | |
|---|---|---|---|---|
| Imidization degree (%)* | 10 | 10 | 73 | 0 |
| Polyimide film | | | | |
| Light transmittance at 400 nm (%) | 77 | 78 | 81 | 79 |
| Total light transmittance (%) | 89 | 87 | 89 | 88 |
| Modulus of elasticity (GPa) | 3.4 | 3.4 | 3.9 | 3.6 |
| Elongation at break (%) | 3 | 9 | 5 | 8 |
| Breaking strength (MPa) | 73 | 107 | 124 | 106 |
| Coefficient of linear thermal expansion | 40 | 41 | 24 | 44 |
| (ppm/K) (50-200° C.) | | | | |
| 5% weight loss temperature (° C.) | 519 | 519 | 523 | 520 |
| Solubility test | ◯ | ◯ | ◯ | ◯ |

*Imidization degree: the amount of the repeating unit represented by the chemical formula (2) relative to the total repeating units

TABLE 2-5

| | | Example 26 | Example 27 | Example 28 | Example 29 |
|---|---|---|---|---|---|
| Polyimide precursor | | | | | |
| Tetracarboxylic | CpODA | | | | |
| acid component | DNDAxx | 11.711 (11.711) | 18.334 (18.334) | 22.000 (8.791) | 11.000 (11.000) |
| (imide compound | s-BPDA | | | | |
| synthesis) | ODPA | | | | |
| (mmol) | | | | | |
| Diamine | DABAN | 4.684 | 7.333 (2.200) | 8.800 (4.400) | 4.400 |
| component | TFMB | 4.684 (4.684) | 3.667 (3.667) | 4.400 (4.400) | |
| (imide compound | PPD | 2.342 | 7.333 | 8.800 | 5.500 |
| synthesis) | FDA | | | | 1.100 (1.100) |
| (mmol) | BAPB | | | | |
| | Imide compound | | | | |
| | TFMB5 | | | | |
| | (TFMB:CpODA = | | | | |
| | 3:2) | | | | |

| | | | | |
|---|---|---|---|---|
| Imidization degree (%)* | 40 | 32 | 31 | 86 |
| Polyimide film | | | | |
| Light transmittance at 400 nm (%) | 78 | 80 | 79 | 67 |
| Total light transmittance (%) | 89 | 89 | 87 | 79 |
| Modulus of elasticity (GPa) | 3.6 | — | — | — |
| Elongation at break (%) | 13 | — | — | — |
| Breaking strength (MPa) | 112 | — | — | — |
| Coefficient of linear thermal expansion | 31 | 31 | 32 | 36 |
| (ppm/K) (50-200° C.) | | | | |
| 5% weight loss temperature (° C.) | 506 | 506 | 506 | 520 |
| Solubility test | ◯ | ◯ | ◯ | ◯ |

| | | | Comparative | | Comparative |
|---|---|---|---|---|---|
| | | Example 30 | Example 8 | Example 31 | Example 9 |
| Polyimide precursor | | | | | |
| Tetracarboxylic | CpODA | | | | |
| acid component | DNDAxx | | | | |
| (imide compound | s-BPDA | 9.468 | 9.468 | | |
| synthesis) | ODPA | | | 12.491 | 12.491 |
| (mmol) | | | | | |
| Diamine | DABAN | | | 6.246 | 6.246 |
| component | TFMB | 9.468 | 9.468 | 6.246 | 6.246 |
| (imide compound | PPD | | | | |
| synthesis) | FDA | | | | |
| (mmol) | BAPB | | | | |
| | Imide compound | | | | |
| | TFMB5 | | | | |
| | (TFMB:CpODA = | | | | |
| | 3:2) | | | | |

| | | | | |
|---|---|---|---|---|
| Imidization degree (%)* | 50 | 0 | 47 | 0 |
| Polyimide film | | | | |
| Light transmittance at 400 nm (%) | 47 | 51 | 31 | 19 |
| Total light transmittance (%) | 86 | 83 | 80 | 76 |
| Modulus of elasticity (GPa) | 4.7 | 5.1 | 6 | 4.7 |
| Elongation at break (%) | 21 | 29 | 15 | 29 |
| Breaking strength (MPa) | 267 | 328 | 235 | 273 |
| Coefficient of linear thermal expansion | 20 | 35 | 20 | 25 |
| (ppm/K) (50-200° C.) | | | | |
| 5% weight loss temperature (° C.) | 575 | 572 | 523 | 520 |
| Solubility test | ◯ | ◯ | ◯ | ◯ |

*Imidization degree: the amount of the repeating unit represented by the chemical formula (2) relative to the total repeating units

TABLE 2-6

| | | | Comparative | |
|---|---|---|---|---|
| | | Example 32 | Example 10 | Example 33 |
| Polyimide precursor | | | | |
| Tetracarboxylic | CpODA | | | |
| acid component | DNDAxx | 10.000 | 10.000 | 10.000 |
| (imide compound | s-BPDA | | | |
| synthesis) | ODPA | | | |
| (mmol) | | | | |
| Diamine | DABAN | 8.000 | 8.000 | 7.000 |
| component | TFMB | | | |
| (imide compound | PPD | 1.000 | 1.000 | 1.000 |
| synthesis) | FDA | | | |
| (mmol) | BAPB | 1.000 | 1.000 | 2.000 |
| | Imide compound | | | |
| | TFMB5 | | | |
| | (TFMB:CpODA = | | | |
| | 3:2) | | | |

| | | | |
|---|---|---|---|
| Imidization degree (%)* | 43 | 0 | 35 |
| Polyimide film | | | |
| Light transmittance at 400 nm (%) | 78 | 78 | 80 |
| Total light transmittance (%) | 89 | 89 | 89 |
| Modulus of elasticity (GPa) | 3.9 | 3.4 | 3.1 |
| Elongation at break (%) | 14 | 28 | 17 |
| Breaking strength (MPa) | 141 | 151 | 128 |
| Coefficient of linear thermal expansion | 20 | 39 | 29 |
| (ppm/K) (50-200° C.) | | | |
| 5% weight loss temperature (° C.) | 522 | 520 | 519 |
| Solubility test | ◯ | ◯ | ◯ |

*Imidization degree: the amount of the repeating unit represented by the chemical formula (2) relative to the total repeating units

### INDUSTRIAL APPLICABILITY

According to the present invention, there may be provided a polyimide precursor, which is produced by thermal imidization, and from which a polyimide having a low coefficient of linear thermal expansion may be obtained without stretching. According to the present invention, there may be also provided a polyimide precursor from which a polyimide having a low coefficient of linear thermal expansion, and excellent heat resistance, solvent resistance and mechanical properties, or a polyimide having excellent transparency in addition thereto may be obtained.

The polyimide obtained from the polyimide precursor of the present invention may have a low coefficient of linear thermal expansion up to a high temperature, and a fine circuit may be easily formed thereon. The polyimide may be suitably used as a film for TAB, a substrate for electric/electronic components, or a wiring board, and may also be suitably used as an insulating film or a protective film for electric/electronic components. The polyimide obtained from the polyimide precursor of the present invention in which an alicyclic tetracarboxylic acid component is used as the tetracarboxylic acid component, in particular, may have high transparency and a low coefficient of linear thermal expansion up to a high temperature, and a fine circuit may be easily formed thereon. The polyimide may be suitably used for the formation of a substrate for use in a display, or the like, in particular. In other words, the polyimide film of this embodiment of the present invention may be suitably used as a transparent substrate for use in a display, or the like, which is colorless and transparent and on which a fine circuit may be formed.

1. A polyimide precursor consisting of
a repeating unit represented by the following chemical formula (1): 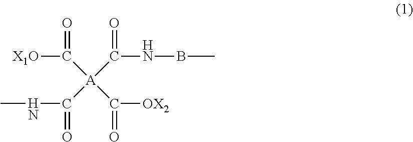
and
a repeating unit represented by the following chemical formula (2): 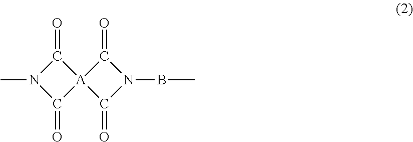
wherein A is a tetravalent group of an alicyclic tetracarboxylic acid, from which carboxyl groups have been removed; B is a divalent group of a diamine, from which amino groups have been removed; with the proviso that the A group and the B group contained in each repeating unit may be the same as, or different from each other; and X₁ and X₂ are each independently hydrogen, an alkyl group having 1 to 6 carbon atoms, or an alkylsilyl group having 3 to 9 carbon atoms,
wherein
the amount of the repeating unit represented by the chemical formula (2) is 30 mol % or more and 90 mol % or less relative to the total repeating units,
50 mol % or more of the total amount of the B group in the chemical formula (1) and the chemical formula (2) is two or more types of divalent group represented by the following chemical formula (3): 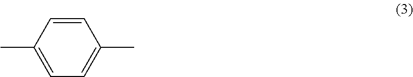
and/or divalent group represented by the following chemical formula (4): 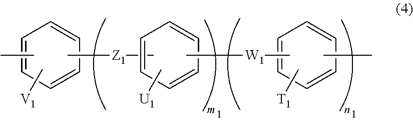
wherein m₁ represents an integer of 1 to 3; n₁ represents an integer of 0 to 3; V₁, U₁ and T₁ each independently represent the one selected from the group consisting of hydrogen atom, methyl group and trifluoromethyl group; and Z₁ and W₁ each independently represent direct bond, or the one selected from the group consisting of groups represented by the formulas: —NHCO—, —CONH—, —COO— and —OCO—, and
at least part of the B group in the chemical formula (1) and/or the chemical formula (2) is a divalent group represented by the following chemical formula (6-1) or (6-2): 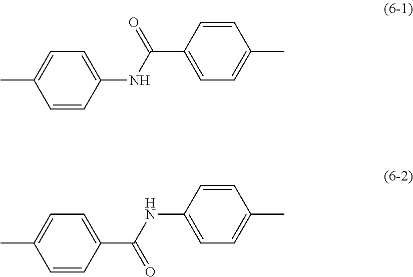
and the polyimide precursor is produced by thermal imidization.

2. The polyimide precursor according to claim 1, wherein the A group in the chemical formula (1) and the chemical formula (2) is one or more of tetravalent group of norbornane-2-spiro-α-cyclopentanone-α′-spiro-2″-norbornane-5,5″,6,6″-tetracarboxylic acid or (4arH,8acH)-decahydro-1t,4t:5c,8c-dimethanonaphthalene-2t,3t,6c,7c-tetracarboxylic acid from which carboxyl groups have been removed.

3. (canceled)

4. The polyimide precursor according to claim 1, wherein the polyimide precursor comprises a structure represented by the following chemical formula (5): 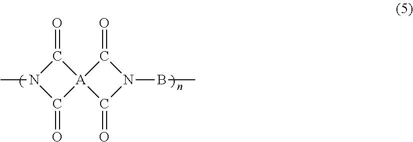
wherein A and B are defined as above; and n is an integer of 1 to 1000.

5. A varnish comprising the polyimide precursor according to claim 1.

6. The varnish according to claim 5, wherein the varnish does not contain a chemical imidizing agent.

7. A process for producing the polyimide precursor according to claim 1, comprising:
heating a tetracarboxylic acid component and a diamine component at a temperature of 100° C. or higher in a solvent which does not contain a chemical imidizing agent to thermally react the components, thereby providing a reaction solution which contains a soluble imide compound comprising a repeating unit represented by the chemical formula (2); and
adding a tetracarboxylic acid component and/or a diamine component to the resulting reaction solution, and performing the reaction at a temperature of lower than 100° C. under the condition that the imidization is suppressed.

8. A process for producing the polyimide precursor according to claim 1, comprising:
heating a tetracarboxylic acid component and a diamine component at a temperature of 100° C. or higher in a solvent which does not contain a chemical imidizing agent to thermally react the components, thereby providing a reaction solution which contains a soluble imide compound comprising a repeating unit represented by the chemical formula (2);
isolating the imide compound comprising a repeating unit represented by the chemical formula (2) from the resulting reaction solution; and
adding the isolated imide compound comprising a repeating unit represented by the chemical formula (2) and a tetracarboxylic acid component and/or a diamine component to a solvent which does not contain a chemical imidizing agent, and performing the reaction at a temperature of lower than 100° C. under the condition that the imidization is suppressed, thereby providing the polyimide precursor.

9. A process for producing the polyimide precursor according to claim 1, comprising:
reacting a tetracarboxylic acid component and a diamine component at a temperature of lower than 100° C. under the condition that the imidization is suppressed in a solvent which does not contain a chemical imidizing agent, thereby providing a reaction solution which contains a (poly)amic acid compound comprising a repeating unit represented by the chemical formula (1); and
heating the reaction solution which contains the (poly)amic acid compound comprising a repeating unit represented by the chemical formula (1) at a temperature of 100° C. or higher to thermally react the compound and convert a part of the repeating unit represented by the chemical formula (1) into a repeating unit represented by the chemical formula (2).

10. A polyimide obtained from the polyimide precursor according to claim 1.

11. A polyimide obtained by subjecting the varnish according to claim 5 to heat treatment.

12. A polyimide film obtained by subjecting the varnish according to claim 5 to heat treatment.

13. A film for TAB, a substrate for electric/electronic components, a wiring board, an insulating film for electric/electronic components, a protective film for electric/electronic components, a substrate for a display, a substrate for a touch panel, or a substrate for a solar battery, comprising the polyimide according to claim 10.
